(19) United States
(12) Patent Application Publication
(10) Pub. No.: US 2026/0343883 A1
(43) Pub. Date: Oct. 29, 2026

(54) MEMORY DEVICE WITH STACKED MEMORY CELLS AND MEMORY PACKAGE INCLUDING THE SAME

(71) Applicant: Samsung Electronics Co., Ltd., Suwon-si (KR)

(72) Inventors: Sangwon Park, Suwon-si (KR); Bongsoon Lim, Suwon-si (KR); Chaehoon Kim, Suwon-si (KR); Hyunhaeng Heo, Suwon-si (KR)

(21) Appl. No.: 19/565,194

(22) Filed: Mar. 12, 2026

(30) Foreign Application Priority Data
Apr. 29, 2025 (KR) 10-2025-0056611

(51) Int. Cl. H10B 43/27; H10B 41/10; H10B 41/27; H10B 41/35; H10B 43/10; H10B 43/35; H10B 80/00; H10W 90/00; H10W 90/20; H10W 90/24; H10W 90/26

(52) U.S. Cl. CPC H10B 43/27; H10B 41/10; H10B 41/27; H10B 41/35; H10B 43/10; H10B 43/35; H10B 80/00; H10W 90/24; H10W 90/26; H10W 90/291; H10W 90/297; H10W 90/722; H10W 90/752; H10W 90/792

(57) ABSTRACT

A memory device includes a gate electrode structure, memory channel structures, a first contact plug and a first electrical connection structure. The gate electrode structure includes gate electrodes. Each of first gate electrodes includes sub-gate electrodes physically separated from each other. The memory channel structures extend through the gate electrode structure. The first contact plug partially extends through the gate electrode structure to contact an upper surface of a second gate electrode, and extends through but being electrically insulated from a gate electrode disposed over the second gate electrode. The first electrical connection structure electrically connects a first sub-gate electrode with a second sub-gate electrode via a third sub-gate electrode. The first and second sub-gate electrodes are disposed at a same level. The third sub-gate electrode is penetrated by the first contact plug and electrically insulated from the first contact plug and the memory channel structures.

### CROSS-REFERENCE TO RELATED APPLICATION

This application claims priority under 35 USC § 119 to Korean Patent Application No. 10-2025-0056611 filed on Apr. 29, 2025, in the Korean Intellectual Property Office (KIPO), the contents of which are herein incorporated by reference in their entirety.

### BACKGROUND

Semiconductor memory devices may be divided into two categories depending upon whether or not they retain stored data when disconnected from a power supply. These categories include volatile memory devices, which lose stored data when disconnected from power, and nonvolatile memory devices, which retain stored data when disconnected from power. While volatile memory devices may perform read and write operations at a high speed, contents stored therein may be lost at power-off. Since nonvolatile memory devices retain contents stored therein even at power-off, they may be used to store data that needs to be retained.

In an electronic system requiring data storage, a high capacity semiconductor memory device that may store large amounts of data can be used. Thus, several approaches to increasing the data storage capacity of the semiconductor memory device have been investigated. a semiconductor memory device including memory cells that may be three-dimensionally stacked has been suggested.

Various methods have been researched to achieve miniaturization and high integration of the semiconductor memory devices.

### SUMMARY

Example implementations relate generally to semiconductor integrated circuits, and more particularly to memory devices and memory package including the memory devices. Semiconductor memory devices including memory cells that may be three-dimensionally stacked are disclosed.

At least one example implementation of the present disclosure provides a memory device capable of reducing size.

At least one example implementation of the present disclosure provides a memory package including the memory device.

According to example implementations, a memory device includes a gate electrode structure, a plurality of memory channel structures, a first contact plug and a first electrical connection structure. The gate electrode structure is disposed on a first substrate, and includes a plurality of gate electrodes sequentially stacked and spaced apart from each other in a first direction perpendicular to an upper surface of the first substrate facing the gate electrode structure. Each of the plurality of gate electrodes extends in a second direction parallel to the upper surface of the first substrate. Each of first gate electrodes that are upper gate electrodes among the plurality of gate electrodes includes a plurality of sub-gate electrodes that are physically separated from each other. The plurality of memory channel structures extend through the gate electrode structure. The first contact plug partially extends through the gate electrode structure to contact an upper surface of a second gate electrode among the plurality of gate electrodes, and extends through but being electrically insulated from a gate electrode among the plurality of gate electrodes that is disposed over the second gate electrode. The upper surface of the second gate electrode faces away from the upper surface of the first substrate. The first electrical connection structure electrically connects a first sub-gate electrode with a second sub-gate electrode via a third sub-gate electrode. The first and second sub-gate electrodes are disposed at a same level among the plurality of sub-gate electrodes. The third sub-gate electrode is penetrated by the first contact plug among the plurality of sub-gate electrodes and electrically insulated from the first contact plug and the plurality of memory channel structures.

According to example implementations, a memory package includes a base substrate and a plurality of memory chips stacked on the base substrate. Each of the plurality of memory chips includes a gate electrode structure, a plurality of memory channel structures, a first contact plug and a first electrical connection structure. The gate electrode structure is disposed on a first substrate, and includes a plurality of gate electrodes sequentially stacked and spaced apart from each other in a first direction perpendicular to an upper surface of the first substrate facing the gate electrode structure. Each of the plurality of gate electrodes extends in a second direction parallel to the upper surface of the first substrate. Each of first gate electrodes that are upper gate electrodes among the plurality of gate electrodes includes a plurality of sub-gate electrodes that are physically separated from each other. The plurality of memory channel structures extend through the gate electrode structure. The first contact plug partially extends through the gate electrode structure to contact an upper surface of a second gate electrode among the plurality of gate electrodes, and extends through but being electrically insulated from a gate electrode among the plurality of gate electrodes that is disposed over the second gate electrode. The upper surface of the second gate electrode faces away from the upper surface of the first substrate. The first electrical connection structure electrically connects a first sub-gate electrode with a second sub-gate electrode via a third sub-gate electrode. The first and second sub-gate electrodes are disposed at a same level among the plurality of sub-gate electrodes. The third sub-gate electrode is penetrated by the first contact plug among the plurality of sub-gate electrodes and electrically insulated from the first contact plug and the plurality of memory channel structures.

According to example implementations, a memory device includes a first substrate, a gate electrode structure, first memory channel structures, second memory channel structures, a first contact plug, a first electrical connection structure, a first string pass transistor, a second string pass transistor and a first string ground transistor. The first substrate includes a first region, a second region and a third region. The first and second regions are spaced apart from each other. The third region is disposed between the first and second regions. The gate electrode structure is disposed on the first, second and third regions of the first substrate, and includes a plurality of gate electrodes sequentially stacked and spaced apart from each other in a first direction perpendicular to an upper surface of the first substrate facing the gate electrode structure. Each of the plurality of gate electrodes extends in a second direction parallel to the upper surface of the first substrate. Each of first gate electrodes that are upper gate electrodes among the plurality of gate electrodes includes a plurality of sub-gate electrodes that are physically separated from each other. The first memory channel structures are disposed on the first region of the first substrate, and extend through the gate electrode structure. The second memory channel structures are disposed on the second region of the first substrate, and extend through the gate electrode structure. The first contact plug is disposed on the third region of the first substrate, partially extends through the gate electrode structure to contact an upper surface of a second gate electrode among the plurality of gate electrodes, and extends through but being electrically insulated from a gate electrode among the plurality of gate electrodes that is disposed over the second gate electrode. The upper surface of the second gate electrode faces away from the upper surface of the first substrate. The first electrical connection structure electrically connects a first sub-gate electrode on the first region with a second sub-gate electrode on the second region via a third sub-gate electrode on the third region. The first and second sub-gate electrodes are spaced apart from each other and disposed at a same level among the plurality of sub-gate electrodes. The third sub-gate electrode is penetrated by the first contact plug among the plurality of sub-gate electrodes and electrically insulated from the first contact plug and the first and second memory channel structures. The first and second sub-gate electrodes are electrically connected with each other and used as a single string selection line. The first string pass transistor is connected to the string selection line, and is adjacent to the first sub-gate electrode. The second string pass transistor is connected to the string selection line, and is adjacent to the second sub-gate electrode. The first string ground transistor is connected to the string selection line, and is adjacent to one of the first and second string pass transistors.

In the memory device and the memory package according to example implementations, the contact plugs electrically connected to the gate electrodes may be disposed at the center other than the edge. Therefore, the gate electrode structure may not have a staircase shape or a step shape, and the processes for forming the gate electrode structure may be simplified.

In addition, in the memory device and the memory package according to example implementations, the upper gate electrodes may be physically separated into the plurality of sub-gate electrodes, and some sub-gate electrodes may be the floating gate electrodes that are penetrated by the contact plugs, electrically insulated from the contact plugs, and electrically insulated from the memory channel structures. Among the plurality of sub-gate electrodes, the sub-gate electrodes that are disposed at the same level and spaced apart from each other may be electrically connected with each other using one of the floating sub-gate electrodes and using the first electrical connection structure. Accordingly, the number of components for driving the upper gate electrodes may be reduced, and the size of the memory device may be reduced.

### BRIEF DESCRIPTION OF THE DRAWINGS

Illustrative, non-limiting example implementations will be more clearly understood from the following detailed description taken in conjunction with the accompanying drawings.

FIGS. 1, 2A, 2B and 3 are diagrams illustrating a memory device according to example implementations.

FIG. 4 is a block diagram illustrating a memory device according to example implementations.

FIG. 5 is a perspective view of an example of a memory block included in a memory cell array of a memory device of FIG. 4.

FIG. 6 is a circuit diagram illustrating an equivalent circuit of a memory block described with reference to FIG. 5.

FIG. 7 is a block diagram illustrating an example of an address decoder included in a memory device of FIG. 4.

FIGS. 8 and 9 are diagrams illustrating examples of a memory device including an address decoder of FIG. 7.

FIGS. 10, 11, 12 and 13 are diagrams illustrating examples of a memory device of FIGS. 1 and 2.

FIG. 14 is a circuit diagram illustrating an example of a memory block included in a memory cell array of a memory device of FIG. 4.

FIG. 15 is a block diagram illustrating an example of an address decoder included in a memory device of FIG. 4.

FIG. 16 is a diagram illustrating an example of a memory device including an address decoder of FIG. 15.

FIGS. 17 and 18 are diagrams illustrating a memory device according to example implementations.

FIGS. 19 and 20 are diagrams illustrating a memory device according to example implementations.

FIGS. 21 and 22 are diagrams illustrating examples of a memory device of FIGS. 19 and 20.

FIGS. 23A and 23B are diagrams illustrating a memory package according to example implementations.

FIG. 24 is a block diagram illustrating a memory system according to example implementations.

FIG. 25 is a cross-sectional view of a memory device according to example implementations.

### DETAILED DESCRIPTION

Various example implementations will be described more fully with reference to the accompanying drawings, in which implementations are shown. The present disclosure may, however, be embodied in many different forms and should not be construed as limited to the implementations set forth herein. Like reference numerals refer to like elements throughout this application.

Hereinafter, a vertical direction substantially perpendicular to an upper surface of a substrate may be referred to as a first direction DR1, and two directions crossing each other among horizontal directions substantially parallel to the upper surface of the substrate may be referred to as second and third directions DR2 and DR3, respectively. For example, the second and third directions DR2 and DR3 may be substantially perpendicular to each other. Each of the first, second and third directions DR1, DR2 and DR3 may include both a direction indicated by an arrow and a direction inverse thereto, in the figures. The first, second and third directions DR1, DR2 and DR3 may be referred to as a Z-axis direction, an X-axis direction and a Y-axis direction, respectively.

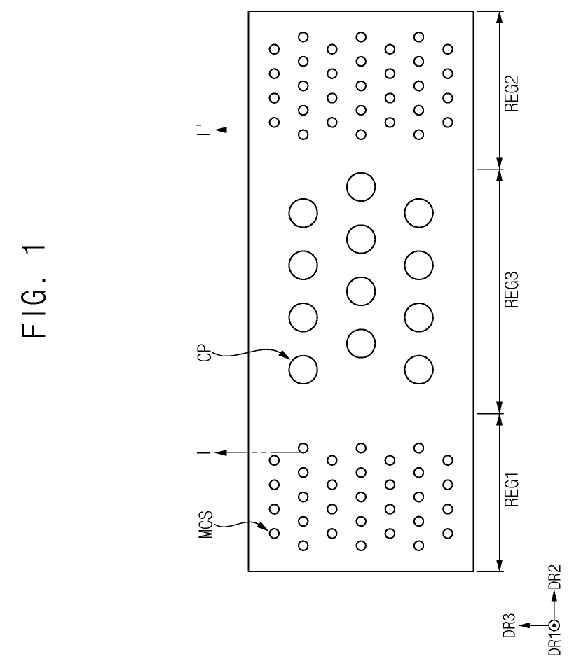

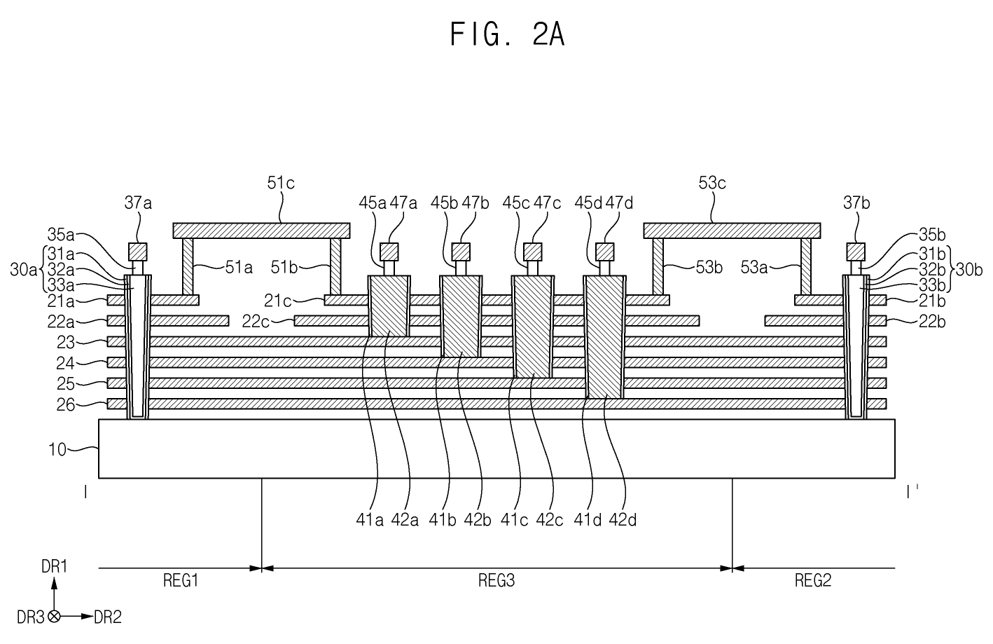

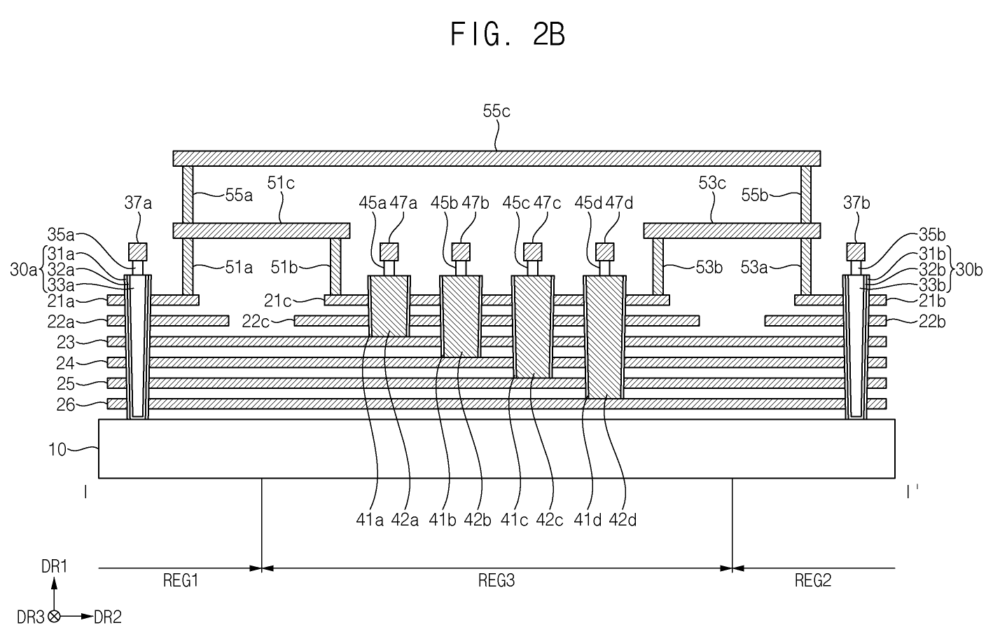

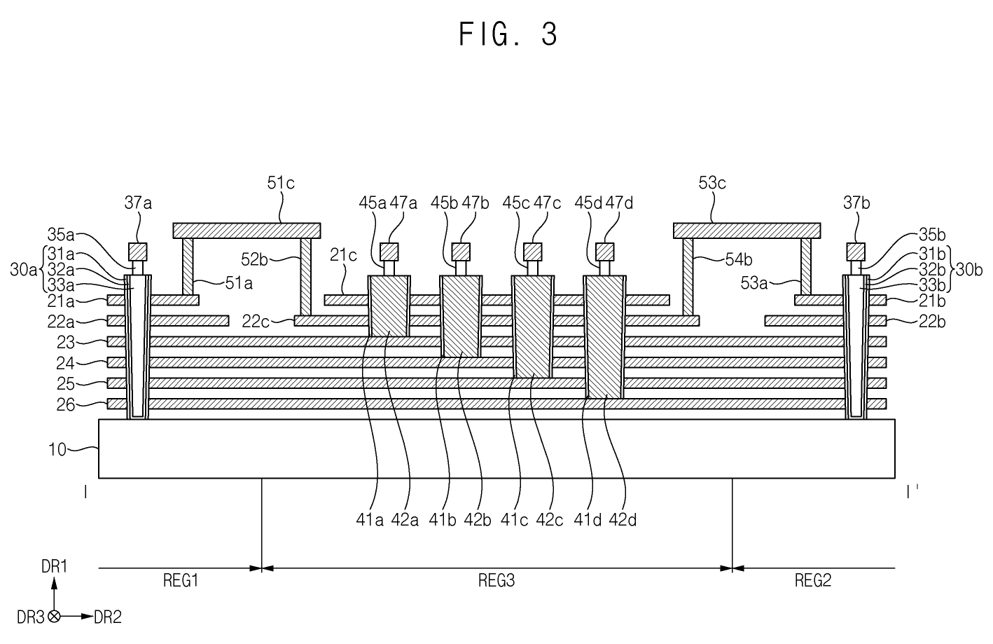

FIGS. 1, 2A, 2B and 3 are diagrams illustrating a memory device according to example implementations. For example, FIG. 1 is a plan view of a memory device, and FIGS. 2A, 2B and 3 are cross-sectional views taken along a line I-I' of FIG. 1, respectively.

Referring to FIGS. 1 and 2A, a memory device includes a gate electrode structure, a plurality of memory channel structures MCS, a plurality of contact plugs CP and a first electrical connection structure, which are disposed and/or formed on a first substrate 10.

The first substrate 10 may include a semiconductor material, e.g., silicon, germanium, silicon-germanium, etc., or a III-V group compound semiconductor, e.g., GaP, GaAs, GaSb, etc. In some example implementations, the first substrate 10 may be a silicon-on-insulator (SOI) substrate or a germanium-on-insulator (GOI) substrate.

The first substrate 10 may include a first region REG1, a second region REGb spaced apart from the first region REG1, and a third region REG3 disposed between the first and second regions REG1 and REG2. For example, the first and second regions REG1 and REGb may be cell regions in which memory cells and the plurality of memory channel structures MCS are disposed and/or formed, and the third region REG3 may be a region in which the plurality of contact plugs CP, which transfer electrical signals to wordlines and ground selection lines that are electrically connected to the memory cells, are disposed and/or formed.

In some example implementations, the memory cells disposed on the first and second regions REG1 and REG2 may form a single memory block and/or a single mat. Unlike a conventional memory device in which contact plugs surround a cell region or are disposed on both sides of the cell region, the memory device according to example implementations may have the plurality of contact plugs CP disposed between the cell regions (e.g., between the first and second regions REG1 and REG2) within a single memory block and/or a single mat, or relatively closer to a center of a single memory block and/or a single mat.

The gate electrode structure includes a plurality of gate electrodes 21a, 21b, 21c, 22a, 22b, 22c, 23, 24, 25 and 26 that are disposed on the first substrate 10.

The plurality of gate electrodes 21a, 21b, 21c, 22a, 22b, 22c, 23, 24, 25 and 26 are sequentially stacked and spaced apart from each other in the first direction DR1. Each of the plurality of gate electrodes 21a, 21b, 21c, 22a, 22b, 22c, 23, 24, 25 and 26 extends in the second direction DR2.

The plurality of gate electrodes 21a, 21b, 21c, 22a, 22b, 22c, 23, 24, 25 and 26 may be disposed at a plurality of levels, respectively, spaced apart from each other in the first direction DR1. As referred to herein, a level can refer to a height or a perpendicular distance from a reference surface, for example, an upper surface of the first substrate 10. A lower level is at a lower height or lesser distance from the reference surface than what a higher level is from the same reference surface. For example, one gate electrode may be disposed at each level. For example, the gate electrode 26 may be disposed at the lowermost level, the gate electrode 25 may be disposed at a level that is higher than the level of the gate electrode 26, the gate electrode 24 may be disposed at a level that is higher than the level of the gate electrode 25, the gate electrode 23 may be disposed at a level that is higher than the level of the gate electrode 24, the gate electrodes 22a, 22b and 22c may be disposed at the same level that is higher than the level of the gate electrode 23, and the gate electrodes 21a, 21b and 21c may be disposed at the same uppermost level that is higher than the level of the gate electrodes 22a, 22b, and 22c.

Among the plurality of gate electrodes 21a, 21b, 21c, 22a, 22b, 22c, 23, 24, 25 and 26, each of upper gate electrodes includes a plurality of sub-gate electrodes 21a, 21b, 21c, 22a, 22b and 22c that are physically separated from each other. For example, the gate electrode at the uppermost level may include the sub-gate electrodes 21a, 21b and 21c that are physically separated from each other, and the gate electrode at a level under the sub-gate electrodes 21a, 21b and 21c may include the sub-gate electrodes 22a, 22b and 22c that are physically separated from each other. For example, the sub-gate electrodes 21a and 22a may be disposed on the first region REG1, the sub-gate electrodes 21b and 22b may be disposed on the second region REG2, and the sub-gate electrodes 21c and 22c may be disposed on the third region REG3.

In some example implementations, when the upper gate electrodes are physically separated into the plurality of sub-gate electrodes 21a, 21b, 21c, 22a, 22b and 22c, the area of each of the sub-gate electrodes 21a, 21b, 21c, 22a, 22b and 22c may be smaller than the area of each of the gate electrode 23, 24, 25 and 26 other than the upper gate electrodes.

In some example implementations, the plurality of gate electrodes 21a, 21b, 21c, 22a, 22b, 22c, 23, 24, 25 and 26 may include a metal having a low resistance, e.g., tungsten, titanium, tantalum, platinum, etc.

In some example implementations, at least one gate electrode at lower levels (e.g., the gate electrode 26) may be used as a ground selection line of the memory device, at least one gate electrode at upper levels (e.g., the gate electrode including the sub-gate electrodes 21a, 21b) may be used as a string selection line of the memory device, and gate electrodes at middle levels (e.g., the gate electrodes 23 and 24) may be used as wordlines of the memory device.

In some example implementations, when the plurality of contact plugs CP are disposed relatively closer to the center of a single memory block and/or a single mat as described above, the plurality of gate electrodes 21a, 21b, 21c, 22a, 22b, 22c, 23, 24, 25 and 26 may extend in the second direction DR2, and may have a constant thickness in the second direction DR2. In addition, lengths in the second direction DR2 of the gate electrodes 23, 24, 25 and 26 other than the upper gate electrodes including the sub-gate electrodes 21a, 21b, 21c, 22a, 22b and 22c may be substantially the same as each other. Therefore, the gate electrode structure may not have a staircase shape or a step shape.

Although FIG. 2A illustrates an example where six gate electrodes are stacked in the first direction DR1 and two upper gate electrodes include sub-gate electrodes that are physically separated, example implementations are not limited thereto.

The plurality of memory channel structures MCS extend into or extend through (or penetrate) the gate electrode structure. The plurality of memory channel structures MCS may include a first memory channel structure 30a and a second memory channel structure 30b.

The first memory channel structure 30a may include a first filling pattern 33a, which may extend in the first direction DR1 and have a pillar shape, a first channel 32a, which may cover a sidewall and a lower surface of the first filling pattern 33a and have a cup shape, and a first charge storage structure 31a on an outer sidewall of the first channel 32a. For example, the first memory channel structure 30a may be disposed on the first region REG1, and first memory cells may be formed on the first region REG1 by the first memory channel structure 30a. The memory device may further include a first via 35a contacting an upper surface of the first memory channel structure 30a, and a first wiring 37a contacting an upper surface of the first via 35a.

In some example implementations, although not illustrated in detail, the first charge storage structure 31a may include a first tunnel insulation pattern, a first charge storage pattern and a first blocking pattern that are sequentially stacked in the horizontal direction from the outer sidewall of the first channel 32a.

Similarly, the second memory channel structure 30b may include a second filling pattern 33b, which may extend in the first direction DR1 and have a pillar shape, a second channel 32b, which may cover a sidewall and a lower surface of the second filling pattern 33b and have a cup shape, and a second charge storage structure 31b on an outer sidewall of the second channel 32b. For example, the second memory channel structure 30b may be disposed on the second region REG2, and second memory cells may be formed on the second region REG2 by the second memory channel structure 30b. The memory device may further include a second via 35b contacting an upper surface of the second memory channel structure 30b, and a second wiring 37b contacting an upper surface of the second via 35b.

In some example implementations, each of the first and second channels 32a and 32b may include, e.g., undoped polysilicon, each of the first and second filling patterns 33a and 33b may include an oxide, e.g., silicon oxide, and each of the first and second charge storage structures 31a and 31b may include an oxide, e.g., silicon oxide, and a nitride, e.g., silicon nitride.

In some example implementations, a plurality of first memory channel structure 30a may be spaced apart from each other in second and third directions DR2 and DR3 on the first region REG1 of the first substrate 10, thereby forming a first memory channel structure array. Similarly, a plurality of second memory channel structure 30b may be spaced apart from each other in the second and third directions DR2 and DR3 on the second region REG2 of the first substrate 10, thereby forming a second memory channel structure array.

In some example implementations, a plurality of first wiring 37a, each of which may extend in the third direction DR3, may be spaced apart from each other in the second direction DR2 on the first region REG1 of the first substrate 10. Similarly, a plurality of second wiring 37b, each of which may extend in the third direction DR3, may be spaced apart from each other in the second direction DR2 on the second region REG2 of the first substrate 10.

In some example implementations, each of the first and second wirings 37a and 37b may be used as a bitline of the memory device.

The plurality of contact plugs CP partially extend through (or penetrate) the gate electrode structure. The plurality of contact plugs CP may include contact plugs 42a, 42b, 42c and 42d that are disposed on the third region REG3.

The contact plug 42a electrically contacts an upper surface of the gate electrode 23, and extends through but is electrically insulated from the gate electrodes 21c and 22c on the gate electrode 23. For example, a spacer 41a may be formed on a sidewall of the contact plug 42a, and the contact plug 42a may be electrically insulated from the gate electrodes 21c and 22c by the spacer 41a. The memory device may further include a via 45a contacting an upper surface of the contact plug 42a, and a wiring 47a contacting an upper surface of the via 45a.

The contact plug 42b electrically contacts an upper surface of the gate electrode 24, and extends through but is electrically insulated from the gate electrodes 21c, 22c and 23 on the gate electrode 24. For example, a spacer 41b may be formed on a sidewall of the contact plug 42b, and the contact plug 42b may be electrically insulated from the gate electrodes 21c, 22c and 23 by the spacer 41b. The memory device may further include a via 45b contacting an upper surface of the contact plug 42b, and a wiring 47b contacting an upper surface of the via 45b.

The contact plug 42c electrically contacts an upper surface of the gate electrode 25, and extends through but is electrically insulated from the gate electrodes 21c, 22c, 23 and 24 on the gate electrode 25. For example, a spacer 41c may be formed on a sidewall of the contact plug 42c, and the contact plug 42c may be electrically insulated from the gate electrodes 21c, 22c, 23 and 24 by the spacer 41c. The memory device may further include a via 45c contacting an upper surface of the contact plug 42c, and a wiring 47c contacting an upper surface of the via 45c.

The contact plug 42d electrically contacts an upper surface of the gate electrode 26, and extends through but is electrically insulated from the gate electrodes 21c, 22c, 23, 24 and 25 on the gate electrode 26. For example, a spacer 41d may be formed on a sidewall of the contact plug 42d, and the contact plug 42d may be electrically insulated from the gate electrodes 21c, 22c, 23, 24 and 25 by the spacer 41d. The memory device may further include a via 45d contacting an upper surface of the contact plug 42d, and a wiring 47d contacting an upper surface of the via 45d.

In other words, each of the contact plugs 42a, 42b, 42c and 42d may contact an upper surface of a corresponding gate electrode included in the gate electrode structure, and may be electrically connected thereto. Each of the contact plugs 42a, 42b, 42c and 42d may extend through other gate electrodes over the corresponding gate electrode, but may be electrically insulated therefrom by each of the spacers 41a, 41b, 41c and 41d.

In some example implementations, a lower surface of the contact plug 42b may be lower than a lower surface of the contact plug 42a, a lower surface of the contact plug 42c may be lower than the lower surface of the contact plug 42b, and a lower surface of the contact plug 42d may be lower than the lower surface of the contact plug 42c.

In some example implementations, each of the contact plugs 42a, 42b, 42c and 42d, the vias 35a, 35b, 45a, 45b, 45c and 45d, and the wirings 37a, 37b, 47a, 47b, 47c and 47d may include a conductive material, e.g., a metal, a metal nitride, a metal silicide, etc. In some example implementations, each of the spacers 41a, 41b, 41c and 41d may include an oxide, e.g., silicon oxide.

In some example implementations, the size (e.g., diameter, radius, etc.) of each of the plurality of contact plugs CP on the plane or in a plan view may be larger than the size of each of the plurality of memory channel structures MCS.

Among the plurality of sub-gate electrodes 21a, 21b, 21c, 22a, 22b and 22c that are included in the upper gate electrodes and physically separated from each other, the sub-gate electrodes 21c and 22c disposed on the third region REG3 may be penetrated by the contact plugs 42a, 42b, 42c and 42d and electrically insulated from the contact plugs the contact plugs 42a, 42b, 42c and 42d, and may also be electrically insulated from the memory channel structures 30a and 30b. In other words, the sub-gate electrodes 21c and 22c disposed on the third region REG3 may be floating gate electrodes that are electrically insulated from both the contact plugs 42a, 42b, 42c and 42d and the memory channel structures 30a and 30b.

The first electrical connection structure electrically connects the sub-gate electrode 21a with the sub-gate electrode 21b via the sub-gate electrode 21c. Among the plurality of sub-gate electrodes 21a, 21b, 21c, 22a, 22b and 22c, the sub-gate electrodes 21a and 21b connected by the first electrical connection structure are disposed at the same level, are spaced apart from each other, and are disposed on the first and second regions REG1 and REG2, respectively. The sub-gate electrode 21c is penetrated by the contact plugs 42a, 42b, 42c and 42d, and is electrically insulated from the contact plugs 42a, 42b, 42c and 42d and the memory channel structures 30a and 30b.

The first electrical connection structure may include vias 51a, 51b, 53a and 53b and wirings 51c and 53c.

The via 51a may contact an upper surface of the sub-gate electrode 21a, the via 51b may contact an upper surface of the sub-gate electrode 21c, and the wiring 51c may contact upper surfaces of the vias 51a and 51b. The sub-gate electrodes 21a and 21c may be electrically connected with each other by the vias 51a and 51b and the wiring 51c. The vias 51a and 51b and the wiring 51c may be referred to as a first-first electrical connection structure.

The via 53a may contact an upper surface of the sub-gate electrode 21b, the via 53b may contact the upper surface of the sub-gate electrode 21c, and the wiring 53c may contact upper surfaces of the vias 53a and 53b. The sub-gate electrodes 21b and 21c may be electrically connected with each other by the vias 53a and 53b and the wiring 53c. The vias 53a and 53b and the wiring 53c may be referred to as a first-second electrical connection structure.

As described above, the sub-gate electrodes 21a and 21c may be electrically connected with each other by the first-first electrical connection structure, the sub-gate electrodes 21b and 21c may be electrically connected with each other by the first-second electrical connection structure, and finally the sub-gate electrodes 21a and 21b may be electrically connected with each other via the first-first and first-second electrical connection structures and the sub-gate electrode 21c.

In some example implementations, each of the vias 51a, 51b, 53a and 53b and the wirings 51c and 53c may include a conductive material, e.g., a metal, a metal nitride, a metal silicide, etc.

In some example implementations, as illustrated in FIG. 2A, the sub-gate electrodes 21a and 21b may be electrically connected with each other via the sub-gate electrode 21c disposed at the same level as them and via the first electrical connection structure.

Although not illustrated in FIG. 2A, the sub-gate electrodes 22a and 22b may also be electrically connected with each other via the sub-gate electrode 22c disposed at the same level as them, and the memory device may further include an electrical connection structure for their electrical connection.

In addition, although not illustrated in FIG. 2A, an insulating material may be filled in the empty spaces between the components.

In some example implementations, a plurality of gate electrode structures may be disposed in the third direction DR3. For example, a plurality of cut regions may be formed between the plurality of gate electrode structures, a plurality of separation patterns may be formed by the plurality of cut regions, and the plurality of gate electrode structures may be separated from each other and spaced apart from each other in the third direction DR3 by the plurality of separation patterns. The plurality of cut regions may be referred to as wordline cut regions.

Referring to FIG. 2B, a configuration of the first electrical connection structure may be partially changed as compared with the example of FIG. 2A. The descriptions repeated with or overlapping with descriptions of FIGS. 1 and 2A will be omitted in the interest of brevity.

The first electrical connection structure may further include vias 55a and 55b and a wiring 55c. The via 55a may contact an upper surface of the wiring 51c, the via 55b may contact an upper surface of the wiring 53c, and the wiring 55c may contact an upper surface of the vias 55a and 55b. The first-first and first-second electrical connection structures may be electrically connected by the vias 55a and 55b and the wiring 55c. The vias 55a and 55b and the wiring 55c may be referred to as a first-third electrical connection structure.

In some example implementations, as illustrated in FIG. 2B, the first-third electrical connection structure may be additionally disposed and/or formed to electrically connect the first-first and first-second electrical connection structures with each other.

Referring to FIG. 3, a configuration of the first electrical connection structure may be partially changed as compared with the example of FIG. 2A. The descriptions repeated with or overlapping with descriptions of FIGS. 1 and 2A will be omitted in the interest of brevity.

The first electrical connection structure electrically connects the sub-gate electrode 21a with the sub-gate electrode 21b via the sub-gate electrode 22c, and may include vias 51a, 52b, 53a and 54b and wirings 51c and 53c. The via 52b may contact an upper surface of the sub-gate electrode 22c, and the wiring 51c may contact upper surfaces of the vias 51a and 52b. The via 54b may contact the upper surface of the sub-gate electrode 22c, and the wiring 53c may contact upper surfaces of the vias 53a and 54b.

In some example implementations, as illustrated in FIG. 3, the sub-gate electrodes 21a and 21b may be electrically connected with each other via the sub-gate electrode 22c disposed at a different level from them and via the first electrical connection structure. Although not illustrated in FIG. 3, the sub-gate electrodes 22a and 22b may be electrically connected with each other via the sub-gate electrode 21c disposed at a different level from them.

In the memory device according to example implementations, the contact plugs 42a, 42b, 42c and 42d electrically connected to the gate electrodes 23, 24, 25 and 26 may be disposed at the center other than the edge. Therefore, the gate electrode structure may not have the staircase shape or the step shape, and the processes for forming the gate electrode structure may be simplified.

In addition, in the memory device according to example implementations, the upper gate electrodes may be physically separated into the plurality of sub-gate electrodes 21a, 21b, 21c, 22a, 22b and 22c, and some sub-gate electrodes 21c and 22c may be the floating gate electrodes that are penetrated by the contact plugs 42a, 42b, 42c and 42d, electrically insulated from the contact plugs 42a, 42b, 42c and 42d, and electrically insulated from the memory channel structures 30a and 30b. Among the plurality of sub-gate electrodes 21a, 21b, 21c, 22a, 22b and 22c, the sub-gate electrodes 21a and 21b that are disposed at the same level and spaced apart from each other may be electrically connected with each other using one of the floating sub-gate electrodes 21c and 22c and using the first electrical connection structure. Accordingly, the number of components for driving the upper gate electrodes may be reduced, and the size of the memory device may be reduced.

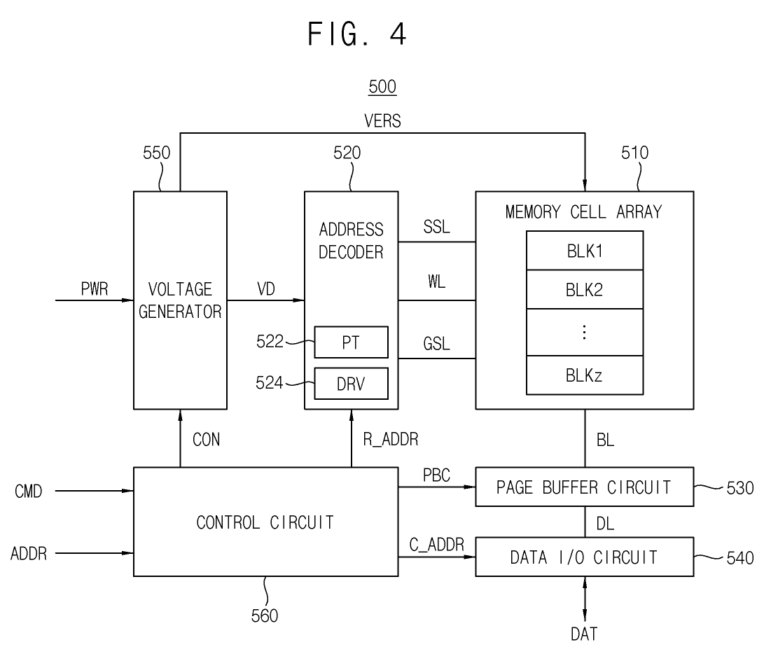

FIG. 4 is a block diagram illustrating a memory device according to example implementations.

Referring to FIG. 4, a memory device 500 includes a memory cell array 510, an address decoder 520, a page buffer circuit 530, a data input/output (I/O) circuit 540, a voltage generator 550 and a control circuit 560. For example, the memory device 500 may be a nonvolatile memory device, e.g., a NAND flash memory device.

The memory cell array 510 may be connected to the address decoder 520 via a plurality of string selection lines SSL, a plurality of wordlines WL and a plurality of ground selection lines GSL. The memory cell array 510 may be further connected to the page buffer circuit 530 via a plurality of bitlines BL. The memory cell array 510 may include a plurality of memory cells (e.g., a plurality of nonvolatile memory cells) that are connected to the plurality of wordlines WL and the plurality of bitlines BL. The memory cell array 510 may be divided into a plurality of memory blocks BLK1, BLK2, ..., BLKz (with z being any positive integer), with each of the plurality of memory blocks BLK1, BLK2, ..., BLKz including memory cells. In addition, each of the plurality of memory blocks BLK1, BLK2, ..., BLKz may be divided into a plurality of pages.

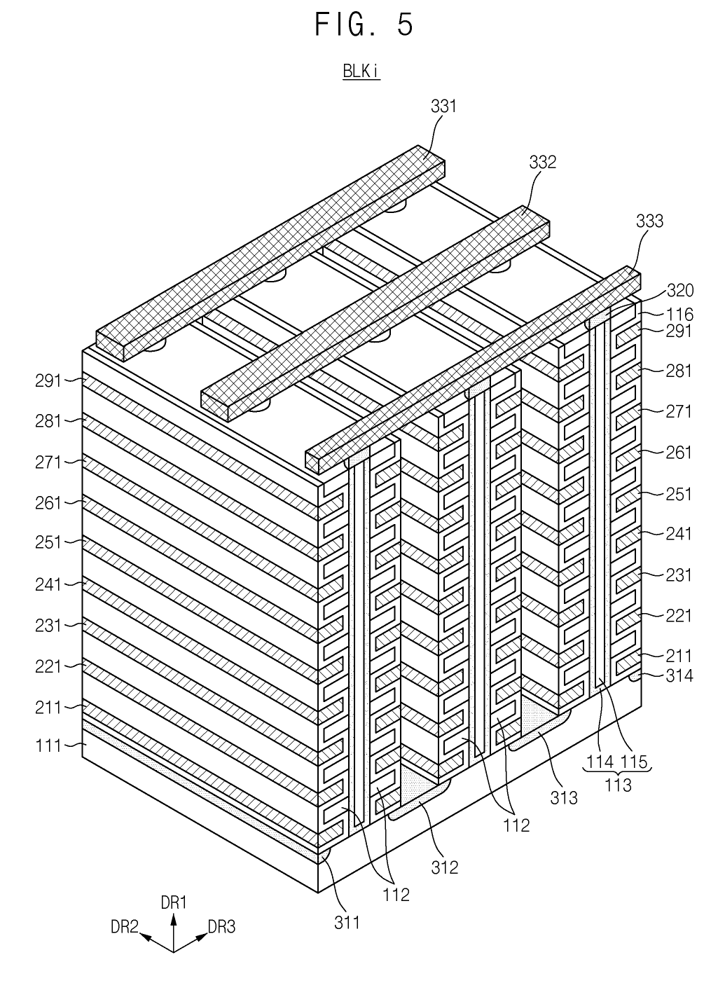

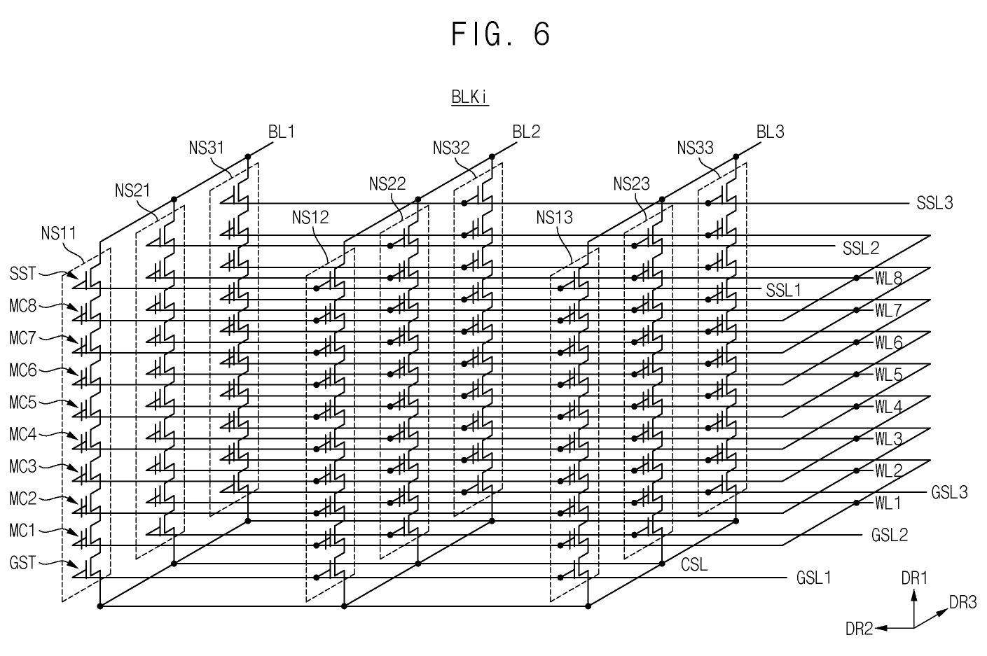

In some example implementations, as will be described in greater detail with reference to FIGS. 5 and 6, the memory cell array 510 may be a three-dimensional memory cell array, which may be formed on a substrate in a three-dimensional structure (or a vertical structure). In this example, the memory cell array 510 may include a plurality of cell strings (e.g., a plurality of vertical NAND strings) that are vertically oriented such that at least one memory cell is located over another memory cell.

The control circuit 560 may receive a command CMD and an address ADDR from outside the memory device 500 (e.g., from a host device and/or a memory controller), and the control circuit 560 may be configured to control erasure, programming and read operations of the memory device 500 based on the command CMD and the address ADDR. An erasure operation may include performing a sequence of erase loops, and a program operation may include performing a sequence of program loops. Each program loop may include a program operation and a program verification operation. Each erase loop may include an erase operation and an erase verification operation. The read operation may include a normal read operation and data recover read operation.

In some example implementations, the control circuit 560 may generate control signals CON, which may be used for controlling the voltage generator 550, and the control circuit 560 may generate control signal PBC, which may be used for controlling the page buffer circuit 530, based on the command CMD. The control circuit 560 may generate a row address R_ADDR and a column address C_ADDR based on the address ADDR. The control circuit 560 may provide the row address R_ADDR to the address decoder 520 and may provide the column address C_ADDR to the data I/O circuit 540.

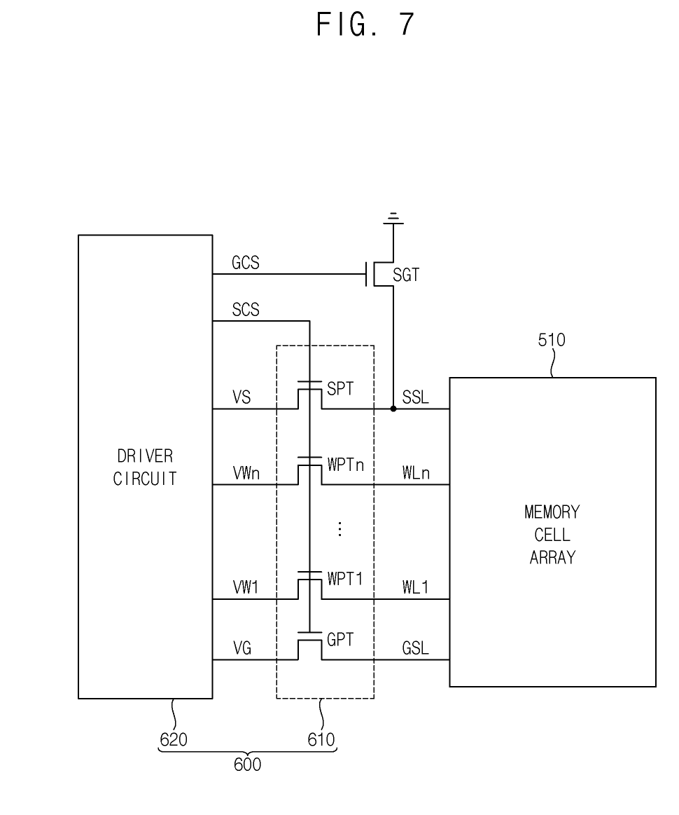

The address decoder 520 may be connected to the memory cell array 510 via the plurality of string selection lines SSL, the plurality of wordlines WL and the plurality of ground selection lines GSL. In some example implementations, in the data erase/write/read operations, the address decoder 520 may determine at least one of the plurality of wordlines WL as a selected wordline, may determine at least one of the plurality of string selection lines SSL as a selected string selection line, and may determine at least one of the plurality of ground selection lines GSL as a selected ground selection line, based on the row address R_ADDR. The address decoder 520 may include a plurality of pass transistors (PT) 522 and a driver circuit (DRV) 524 for driving the plurality of string select lines SSL, the plurality of word lines WL and the plurality of ground select lines GSL. More detailed configurations of the plurality of pass transistors 522 and the driver circuit 524 will be described with reference to FIG. 7.

The voltage generator 550 may generate voltages VS that may be used for an operation of the memory device 500 based on a power PWR and the control signals CON. The voltages VS may be applied to the plurality of string selection lines SSL, the plurality of wordlines WL and the plurality of ground selection lines GSL via the address decoder 520. In addition, the voltage generator 550 may generate an erase voltage VERS that is used for the data erase operation based on the power PWR and the control signals CON.

The page buffer circuit 530 may be connected to the memory cell array 510 via the plurality of bitlines BL. The page buffer circuit 530 may include a plurality of page buffers. The page buffer circuit 530 may store data DAT to be programmed into the memory cell array 510 or may read data DAT sensed from the memory cell array 510. In other words, the page buffer circuit 530 may operate as a write driver and/or as a sensing amplifier according to an operation mode of the memory device 500.

The data I/O circuit 540 may be connected to the page buffer circuit 530 via data lines DL. The data I/O circuit 540 may provide the data DAT from an outside of the memory device 500 to the memory cell array 510 via the page buffer circuit 530 or may provide the data DAT from the memory cell array 510 to the outside of the memory device 500, based on the column address C_ADDR.

FIG. 5 is a perspective view of an example of a memory block included in a memory cell array of a memory device of FIG. 4.

Referring to FIG. 5, a memory block BLKi may include a plurality of cell strings (e.g., a plurality of vertical NAND strings) which may be formed on a substrate in a three-dimensional structure (or a vertical structure). The memory block BLKi may include structures extending along the first, second and third directions DR1, DR2 and DR3. For example, the memory block BLKi may correspond to a portion of the first region REG1 or a portion of the second region REG2 in FIG. 1.

A substrate 111 (e.g., the upper substrate of the first semiconductor layer L1) may be provided. In some example implementations, the substrate 111 may have a well of a first type of charge carrier impurity (e.g., a first conductivity type) therein. In some example implementations, the substrate 111 may have a p-well formed by implanting a group 3 (III) element such as boron (B). However, the conductive type of the substrate 111 is not limited to p-type.

A plurality of doping regions 311, 312, 313 and 314 arranged along the third direction DR3 are provided in/on the substrate 111. These plurality of doping regions 311 to 314 may have a second type of charge carrier impurity (e.g., a second conductivity type) different from the first type of the substrate 111. In some example implementations, the first to fourth doping regions 311 to 314 may have n-type. However, the conductive type of the first to fourth doping regions 311 to 314 is not limited to n-type.

A plurality of insulation materials 112 that extend along the second direction DR2 are sequentially provided in the first direction DR1 on a region of the substrate 111 between the first and second doping regions 311 and 312. In some example implementations, the plurality of insulation materials 112 are provided in the first direction DR1, and are spaced apart by a specific distance. In some example implementations, the insulation materials 112 may include an insulation material such as an oxide layer.

A plurality of pillars 113 that penetrate or extend though the insulation materials in the first direction DR1 are sequentially provided and spaced apart along the second direction DR2 on a region of the substrate 111 between the first and second doping regions 311 and 312. In some example implementations, the plurality of pillars 113 may penetrate the insulation materials 112 and may contact the substrate 111.

In some example implementations, each pillar 113 may include a plurality of materials. In some example implementations, a channel layer 114 of each pillar 113 may include a silicon material having a first conductivity type. In some example implementations, the channel layer 114 of each pillar 113 may include a silicon material having the same conductivity type as the substrate 111. In some example implementations, the channel layer 114 of each pillar 113 includes p-type silicon. However, the channel layer 114 of each pillar 113 is not limited to the p-type silicon. An internal material 115 of each pillar 113 includes an insulation material. In some example implementations, the internal material 115 of each pillar 113 may include an insulation material such as a silicon oxide. In some examples, the internal material 115 of each pillar 113 may include an air gap. The term “air” as discussed herein, may refer to atmospheric air, or other gases that may be present during the manufacturing process.

An insulation layer 116 may be provided along the exposed surfaces of the insulation materials 112, the pillars 113, and the substrate 111, on a region between the first and second doping regions 311 and 312. In some example implementations, the insulation layer 116 provided on surfaces of the insulation material 112 may be interposed between pillars 113 and a plurality of stacked first conductive materials 211, 221, 231, 241, 251, 261, 271, 281 and 291, as illustrated. In some examples, the insulation layer 116 may not be provided between and may be absent from between the first conductive materials 211 to 291 corresponding to ground selection lines GSL (e.g., 211) and string selection lines SSL (e.g., 291). In this example, the ground selection lines GSL are the lowermost ones of the stack of first conductive materials 211 to 291 and the string selection lines SSL are the uppermost ones of the stack of first conductive materials 211 to 291.

The plurality of first conductive materials 211 to 291 may be provided on surfaces of the insulation layer 116, in a region between the first and second doping regions 311 and 312. In some example implementations, the first conductive material 211 extending along the second direction DR2 may be provided between the insulation material 112 adjacent to the substrate 111 and the substrate 111. In greater detail, the first conductive material 211 extending along the second direction DR2 is provided between the insulation layer 116 at the bottom of the insulation material 112 adjacent to the substrate 111 and the substrate 111.

A first conductive material extending along the second direction DR2 may be provided between the insulation layer 116 at the top of the specific insulation material among the insulation materials 112 and the insulation layer 116 at the bottom of a specific insulation material among the insulation materials 112. In some example implementations, a plurality of first conductive materials 221 to 281 extending along the second direction DR2 may be provided between the insulation materials 112 and it may be understood that the insulation layer 116 is provided between the insulation materials 112 and the first conductive materials 221 to 281. The first conductive materials 211 to 291 may be formed of a conductive metal, but in other implementations the first conductive materials 211 to 291 may include a conductive material such as a polysilicon.

The same structures as those on the first and second doping regions 311 and 312 may be provided in a region between the second and third doping regions 312 and 313. In the region between the second and third doping regions 312 and 313, a plurality of insulation materials 112 are provided, which extend along the second direction DR2. And, a plurality of pillars 113 may be provided that are arranged sequentially along the second direction DR2 and penetrate or extend the plurality of insulation materials 112 along the first direction DR1. An insulation layer 116 may be provided on the exposed surfaces of the plurality of insulation materials 112 and the plurality of pillars 113, and a plurality of first conductive materials 211 to 291 may extend along the second direction DR2. Similarly, the same structures as those on the first and second doping regions 311 and 312 may be provided in a region between the third and fourth doping regions 313 and 314.

A plurality of drain regions may be are provided on the plurality of pillars 113, respectively. The drain regions 320 may include silicon materials doped with a second type of charge carrier impurity. In some example implementations, the drain regions 320 may include silicon materials doped with an n-type dopant. In some example implementations, the drain regions 320 include n-type silicon materials. However, the drain regions 320 are not limited to n-type silicon materials.

On the drain regions, a plurality of second conductive materials 331, 332 and 333 are provided, which extend along the third direction DR3. The second conductive materials 331 to 333 may be arranged along the second direction DR2, being spaced apart from each other by a specific distance. The second conductive materials 331 to 333 are respectively connected to the drain regions 320 in a corresponding region. The drain regions 320 and the second conductive material 333 extending along the third direction DR3 may be connected through each contact plug. Each contact plug may be, in some example implementations, a conductive plug formed of a conductive material such as a metal. The second conductive materials 331 to 333 may include metal materials. The second conductive materials 331 to 333 may include conductive materials such as a polysilicon.

In the example of FIG. 5, the first conductive materials 211 to 291 may be used to form the wordlines WL, the string selection lines SSL and the ground selection lines GSL. In some example implementations, the first conductive materials 221 to 281 may be used to form the wordlines WL, where conductive materials belonging to the same layer may be interconnected. The second conductive materials 331 to 333 may be used to form the bitlines BL. The number of layers of the first conductive materials 211 to 291 may be changed variously according to process and control techniques.

FIG. 6 is a circuit diagram illustrating an equivalent circuit of a memory block described with reference to FIG. 5.

A memory block BLKi of FIG. 6 may be formed on a substrate in a three-dimensional structure (or a vertical structure). In some example implementations, a plurality of NAND strings included in the memory block BLKi may be formed in a direction perpendicular to the substrate.

Referring to FIG. 6, the memory block BLKi may include a plurality of NAND strings NS11, NS12, NS13, NS21, NS22, NS23, NS31, NS32 and NS33 connected between bitlines BL1, BL2 and BL3 and a common source line CSL. Each of the NAND strings NS11 to NS33 may include a string selection transistor SST, a plurality of memory cells MC1, MC2, MC3, MC4, MC5, MC6, MC7 and MC8, and a ground selection transistor GST. In some example implementations, the bitlines BL1 to BL3 may correspond to the second conductive materials 331 to 333 in FIG. 5, and the common source line CSL may be formed by interconnecting the first to fourth doping regions 311 to 314 in FIG. 5.

Each string selection transistor SST may be connected to a corresponding string selection line (one of SSL1, SSL2 and SSL3). The plurality of memory cells MC1 to MC8 may be connected to corresponding wordlines WL1, WL2, WL3, WL4, WL5, WL6, WL7 and WL8, respectively. Each ground selection transistor GST may be connected to a corresponding ground selection line (one of GSL1, GSL2 and GSL3). Each string selection transistor SST may be connected to a corresponding bitline (e.g., one of BL1 to BL3), and each ground selection transistor GST may be connected to the common source line CSL. In the example of FIG. 6, some of the string selection transistors SST are connected to the same bitline (e.g., one of BL1 to BL3) to connect corresponding NAND strings to the same bitline up appropriate selection via selection voltages applied to the appropriate sting selection lines SSL1 to SSL3 and ground selection lines GSL1 to GSL3.

The cell strings connected in common to one bitline may form one column, and the cell strings connected to one string selection line may form one row. In some example implementations, the cell strings NS11, NS21 and NS31 connected to the first bitline BL1 may correspond to a first column, and the cell strings NS11, NS12 and NS13 connected to the first string selection line SSL1 may form a first row.

Wordlines (e.g., WL1) having the same height may be commonly connected, and the ground selection lines GSL1 to GSL3 and the string selection lines SSL1 to SSL3 may be separated. Memory cells located at the same semiconductor layer share a wordline. Cell strings in the same row share a string selection line. The common source line CSL is connected in common to all of cell strings.

In FIG. 6, the memory block BLKi is illustrated to be connected to eight wordlines WL1 to WL8 and three bitlines BL1 to BL3, and each of the NAND strings NS11 to NS33 is illustrated to include eight memory cells MC1 to MC8. However, example implementations are not limited thereto. In some example implementations, each memory block may be connected to any number of wordlines and bitlines, and each NAND string may include any number of memory cells.

A three-dimensional vertical array structure may include vertical NAND strings that are vertically oriented such that at least one memory cell is located over another memory cell. The at least one memory cell may comprise a charge trap layer. The following patent documents, which are hereby incorporated by reference in their entirety, describe suitable configurations for a memory cell array including a 3D vertical array structure, in which the three-dimensional memory array is configured as a plurality of levels, with wordlines and/or bitlines shared between levels: U.S. Pat. Nos. 7,679,133; 8,553,466; 8,654,587; 8,559,235; and US Pat. Pub. No. 2011/0233648.

Although FIG. 6 illustrates an example where each cell string includes one string selection transistor SST, example implementations are not limited thereto.

In some example implementations, each cell string may include two or more string selection transistors SST and may be connected to two or more string selection lines. In some example implementations, at least one string selection transistor SST adjacent to the bitline among the two or more string selection transistors SST may be used as a gate induced drain leakage (GIDL) string selection transistor for erasing data using a GIDL phenomenon, and a string selection line connected to the GIDL string selection transistor may be used as a GIDL string selection line.

FIG. 7 is a block diagram illustrating an example of an address decoder included in a memory device of FIG. 4.

Referring to FIG. 7, an address decoder 600 may be connected to the memory cell array 510 through a string selection line SSL, wordlines WL1, ..., WLn, and a ground selection line GSL, and may include a pass switch circuit 610 and a driver circuit 620. The address decoder 600 may be referred to as a row decoder, a wordline decoder, or the like.

The pass switch circuit 610 may include a plurality of pass transistors SPT, WPT1, ..., WPTn and GPT. For example, the plurality of pass transistors SPT, WPT1 to WPTn and GPT may include a string pass transistor SPT connected to the string selection line SSL, wordline pass transistors WPT1 to WPTn connected to the wordlines WL1 to WLn, and a ground pass transistor GPT connected to the ground selection line GSL.

The driver circuit 620 may control switching operations of the plurality of pass transistors SPT, WPT1 to WPTn and GPT, and may control operations of supplying voltages VS, VW1, ..., VWn, VG to the memory cell array 510 through the plurality of pass transistors SPT, WPT1 to WPTn and GPT. For example, the switching operations of the plurality of pass transistors SPT, WPT1 to WPTn and GPT may be controlled by a plurality of switching control signals SCS, and timings at which the voltages VS, VW1 to VWn, VG are applied to the memory cell array 510 may be controlled by the switching operations of the plurality of pass transistors SPT, WPT1 to WPTn and GPT.

The memory device may further include a string ground transistor SGT connected to the string selection line SSL. For example, a switching operation of the string ground transistor SGT may be controlled by a ground control signal GCS provided from the driver circuit 620, and the string ground transistor SGT may supply a ground voltage for discharging an unselected string in response to the ground control signal GCS.

Although the memory cell array and the memory device according to some example implementations is described based on a NAND flash memory device, the memory device according to some example implementations may be any nonvolatile memory device, e.g., a phase-change random access memory (PRAM), a resistive random access memory (RRAM), a magnetic random access memory (MRAM), a ferroelectric random access memory (FRAM), and so on.

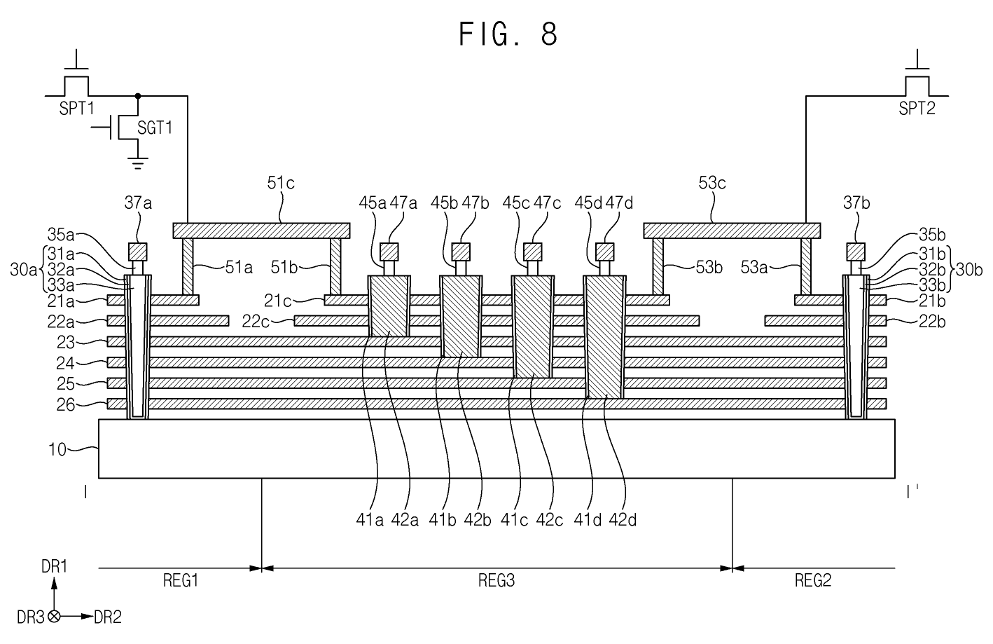

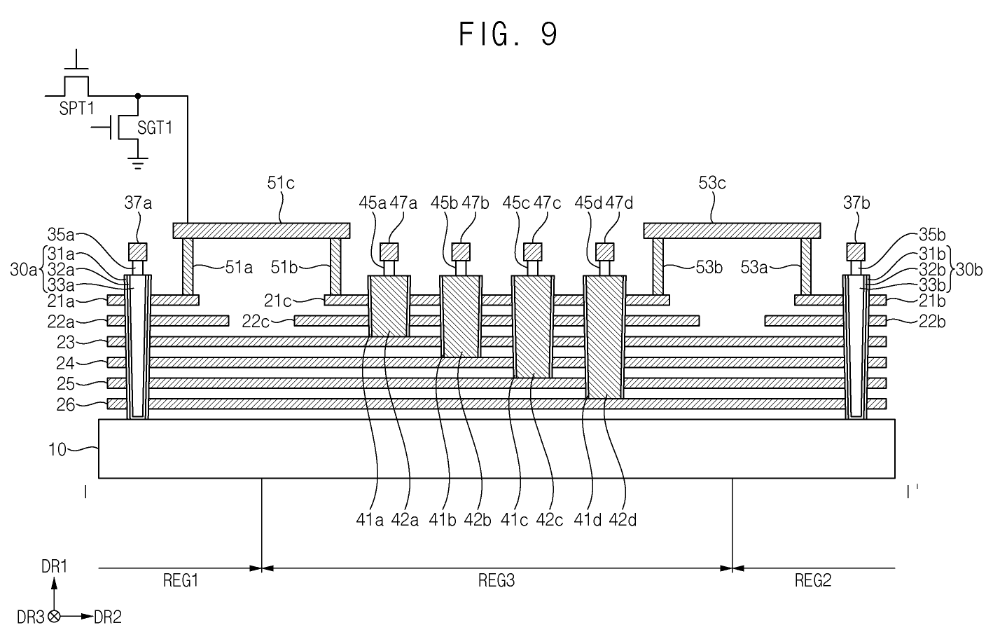

FIGS. 8 and 9 are diagrams illustrating examples of a memory device including an address decoder of FIG. 7.

Referring to FIGS. 8 and 9, an example of the memory device of FIG. 2A where the sub-gate electrodes 21a and 21b are electrically connected with each other via the sub-gate electrode 21c and the first electrical connection structure and are used as a single string selection line is illustrated.

In some example implementations, as illustrated in FIG. 8, the memory device may further include a first string pass transistor SPT1, a second string pass transistor SPT2 and a first string ground transistor SGT1.

The first string pass transistor SPT1 may be connected to the string selection line, and may be disposed and connected to be adjacent to the sub-gate electrode 21a. Being adjacent to the sub-gate electrode 21a can refer to being nearer to the sub-gate electrode 21a than to the sub-gate electrode 21b. The second string pass transistor SPT2 may be connected to the string selection line, and may be disposed and connected to be adjacent to the sub-gate electrode 21b. Being adjacent to the sub-gate electrode 21b can refer to being nearer to the sub-gate electrode 21b than to the sub-gate electrode 21a. The first string ground transistor SGT1 may be connected to the string selection line, and may be disposed and connected to be adjacent to the first string pass transistor SPT1. Being adjacent to the first string pass transistor SPT1 can refer to being nearer to the first string pass transistor SPT1 than to the second string pass transistor SPT2.

Although not illustrated in detail, in the example of FIG. 8 where two string pass transistors and one string ground transistor are included, the first string ground transistor SGT1 may be disposed and connected to be adjacent to the second string pass transistor SPT2. Being adjacent to the second string pass transistor SPT2 can refer to being nearer to the second string pass transistor SPT2 than to the first string pass transistor SPT1.

In some example implementations, as illustrated in FIG. 9, the memory device may further include a first string pass transistor SPT1 and a first string ground transistor SGT1. The first string pass transistor SPT1 and the first string ground transistor SGT1may be substantially the same as those described with reference to FIG. 8.

Although not illustrated in detail, in the example of FIG. 9 where one string pass transistor and one string ground transistor are included, the first string pass transistor SPT1 and the first string ground transistor SGT1 may be disposed and connected to be adjacent to the sub-gate electrode 21b. Being adjacent to the sub-gate electrode 21b can refer to being nearer to the sub-gate electrode 21b than to the sub-gate electrode 21a. In some implementations, the first string pass transistor SPT1 may be disposed and connected to be adjacent to one of the sub-gate electrodes 21a and 21b and the first string ground transistor SGT1 may be disposed and connected to be adjacent to the other of the sub-gate electrodes 21a and 21b. Being adjacent to one of the sub-gate electrodes 21a and 21b refers to being nearer to the one sub-gate electrode than to the other sub-gate electrode.

When the sub-gate electrodes 21a and 21b are not electrically connected with each other, e.g., when the memory device does not include the first electrical connection structure according to example implementations, each of the sub-gate electrodes 21a and 21b may operate as an individual string selection line, and a string pass transistor and a string ground transistor may be required to drive each string selection line. In other words, two string pass transistors and two string ground transistors should be required.

In contrast, when the sub-gate electrodes 21a and 21b are electrically connected with each other via the sub-gate electrode 21c and the first electrical connection structure according to example implementations, the sub-gate electrodes 21a and 21b may operate as a single string selection line. Thus, among the two string pass transistors and two string ground transistors described above, one string ground transistor may be omitted as illustrated in FIG. 8, and one string pass transistor and one string ground transistor may be omitted as illustrated in FIG. 9. Accordingly, the number of components for driving the string selection line may be reduced, and the size of the memory device may be reduced.

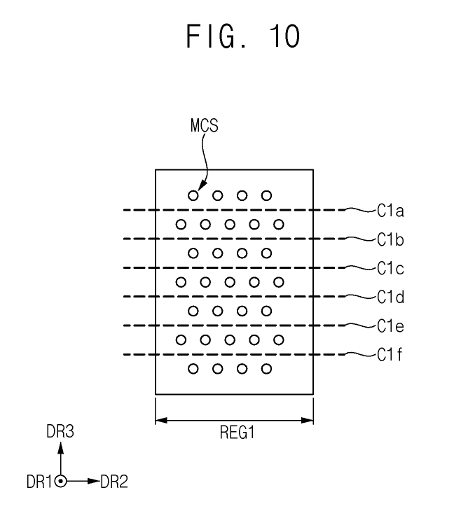

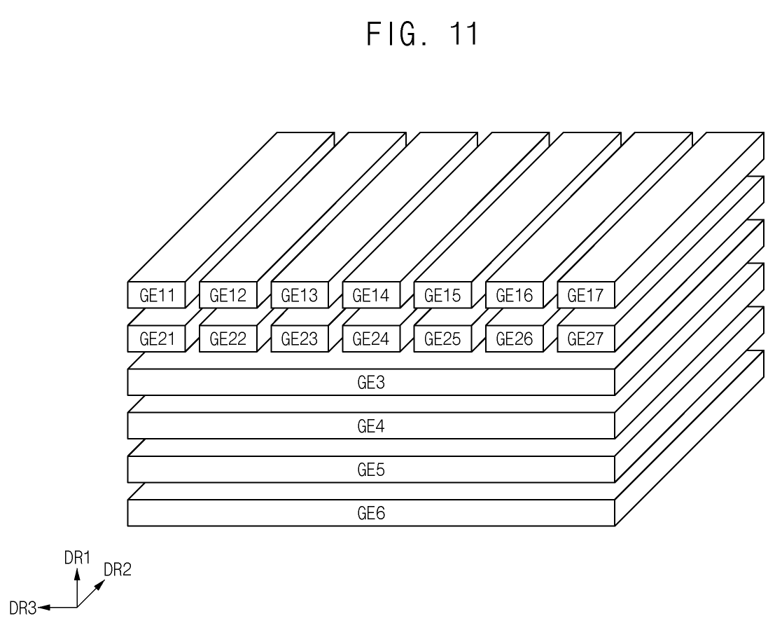

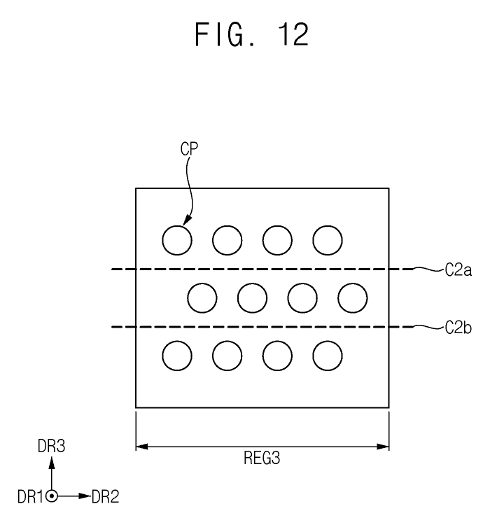

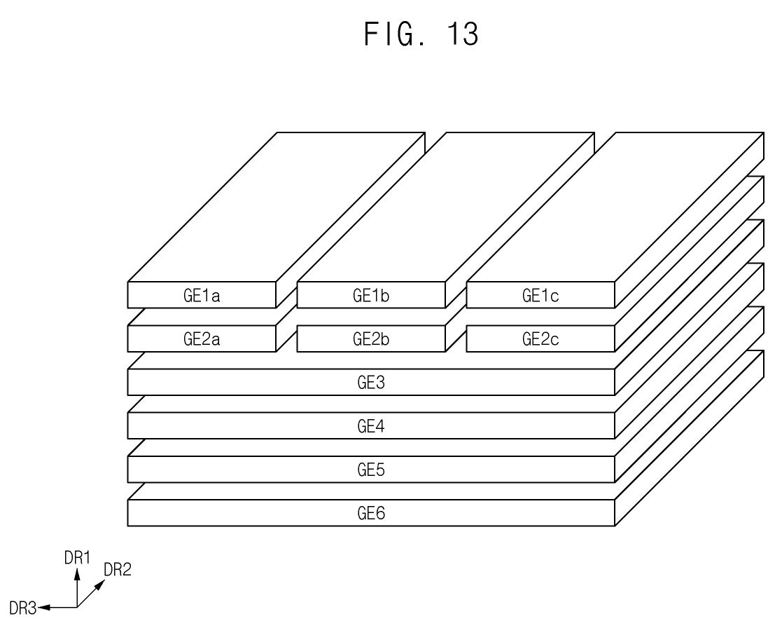

FIGS. 10, 11, 12 and 13 are diagrams illustrating examples of a memory device of FIGS. 1 and 2. For example, FIG. 10 is a plan view of an example of the first region REG1 in FIG. 1, FIG. 11 is a perspective view of a gate electrode structure on the first region REG1 in FIG. 10, FIG. 12 is a plan view of an example of the third region REG3 in FIG. 1, and FIG. 13 is a perspective view of a gate electrode structure on the third region REG3 in FIG. 12.

Referring to FIGS. 10 and 11, in the first region REG1, the upper sub-gate electrodes 21a and 22a may be separated into a plurality of parts by a plurality of cut regions C1a, C1b, C1c, C1d, C1e and C1f. For example, a plurality of separation patterns may be formed by the plurality of cut regions C1a, C1b, C1c, C1d, C1e and C1f, and the sub-gate electrodes 21a and 22a may be separated from each other and spaced apart from each other in the third direction DR3 by the plurality of separation patterns.

Therefore, unlike the gate electrodes GE3, GE4, GE5 and GE6 that correspond to the gate electrodes 23, 24, 25 and 26 and are formed as a single part at a single level, the sub-gate electrode 21a may be divided into a plurality of parts, e.g., seven parts GE11, GE12, GE13, GE14, GE15, GE16 and GE17, and the sub-gate electrode 22a may be divided into a plurality of parts, e.g., seven parts GE21, GE22, GE23, GE24, GE25, GE26 and GE27. For example, the area of each of the plurality of parts GE11, GE12, GE13, GE14, GE15, GE16, GE17, GE21, GE22, GE23, GE24, GE25, GE26 and GE27 may be smaller than the area of each of the sub-gate electrodes 21a and 22a.

In some example implementations, the gate electrodes GE3, GE4, GE5 and GE6 may be used as wordlines and ground selection lines, and the plurality of parts GE11, GE12, GE13, GE14, GE15, GE16, GE17, GE21, GE22, GE23, GE24, GE25, GE26 and GE27 of the sub-gate electrodes 21a and 22a may be used as string selection lines. In this example, the plurality of cut regions C1a, C1b, C1c, C1d, C1e and C1f may be referred to as string selection line cut regions.

In some example implementations, at least some portions of the memory channel structures MCS may also be cut by the plurality of cut regions C1a, C1b, C1c, C1d, C1e and C1f.

Although not illustrated in FIGS. 10 and 11, as with the first region REG1, in the second region REG2, each of the sub-gate electrodes 21b and 22b may be divided into a plurality of parts, e.g., seven parts.

In some example implementations, one part (e.g., the part GE11) of the sub-gate electrodes 21a and 22a on the first region REG1 and one part of the sub-gate electrodes 21b and 22b on the second region REG2 corresponding thereto (e.g., disposed at the same level and at the same position) may be electrically connected to each other via the sub-gate electrode 21c and the first electrical connection structure, and may be used as a single string selection line.

Referring to FIGS. 12 and 13, in the third region REG1, the upper sub-gate electrodes 21c and 22c may be separated into a plurality of parts by a plurality of cut regions C2a and C2b. For example, a plurality of separation patterns may be formed by the plurality of cut regions C2a and C2b, and the sub-gate electrodes 21c and 22c may be separated from each other and spaced apart from each other in the third direction DR3 by the plurality of separation patterns.

Therefore, the sub-gate electrode 21c may be separated into a plurality of parts, e.g., three parts GE1a, GE1b and GE1c, and the sub-gate electrode 22c may be separated into a plurality of parts, e.g., three parts GE2a, GE2b, GE2c. For example, the area of each of the plurality of parts GE1a, GE1b, GE1c, GE2a, GE2b and GE2c may be smaller than the area of each of the sub-gate electrodes 21c and 22c.

In some example implementations, the plurality of cut regions C2a and C2b may be formed so as not to cut the plurality of contact plugs CP.

In some example implementations, the sub-gate electrodes 21a and 21b at the same level may be electrically connected with each other via one part (e.g., the part GE1a) of the sub-gate electrodes 21c and 22c and the first electrical connection structure, and may be used as a single string selection line.

In some example implementations, the memory device according to example implementations may be implemented by combining the example of FIGS. 10 and 11 and the example of FIGS. 12 and 13. For example, the part GE11 on the first region REG1 and a corresponding part on the second region REG2 that is disposed at the same level and at the same position may be electrically connected with each other via the part GE1a, and the part GE12 on the first region REG1 and a corresponding part on the second region REG2 that is disposed at the same level and at the same position may be electrically connected with each other via the part GE1b.

Although FIGS. 10, 11, 12 and 13 illustrate a specific number of the cut regions C1a, C1b, C1c, C1d, C1e, C1f, C2a and C2b and a specific number of the parts GE11, GE12, GE13, GE14, GE15, GE16, GE17, GE21, GE22, GE23, GE24, GE25, GE26, GE27, GE1a, GE1b, GE1c, GE2a, GE2b and GE2c that are separated by the cut regions C1a, C1b, C1c, C1d, C1e, C1f, C2a and C2b, example implementations are not limited thereto.

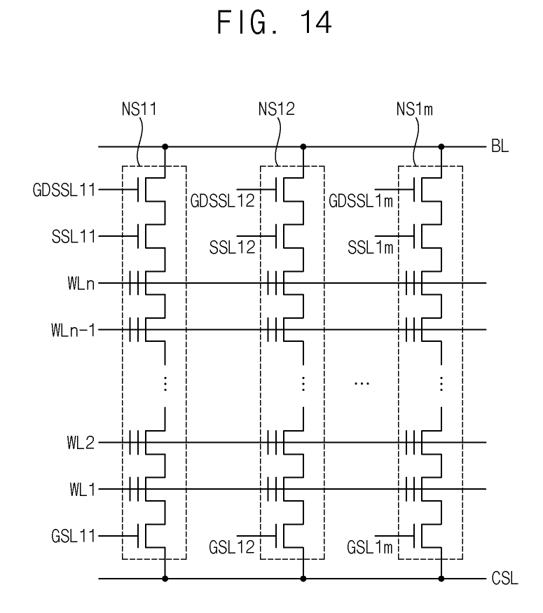

FIG. 14 is a circuit diagram illustrating an example of a memory block included in a memory cell array of a memory device of FIG. 4.

For convenience of illustration, FIG. 14 illustrates a two-dimensional version of a memory block including a plurality of cell strings NS11, NS12, ..., NS1m connected to one bitline BL and one common source line CSL. However, it will be understood that the memory block may have a three-dimensional structure of a plurality of bitlines as described with reference to FIGS. 5 and 6.

Referring to FIG. 14, the memory block may include the plurality of cell strings NS11 to NS1m commonly connected between the bitline BL and the common source line CSL, where m is a positive integer. The cell strings NS11 to NS1m may include GIDL string selection transistors controlled by GIDL string selection lines GDSSL1, GDSSL12, ..., GDSSL1m, string selection transistors controlled by string selection lines SSL11, SSL12, ..., SSL1m, memory cells controlled by wordlines WL1, WL2, ..., WLn-1, WLn, and ground selection transistors controlled by ground selection lines GSL11, GSL12, ..., GSL1m, respectively.

The GIDL string selection lines GDSSL1 to GDSSL1m and the GIDL string selection transistors connected thereto may be used for erasing data stored in the memory block using a GIDL phenomenon during an erase operation.

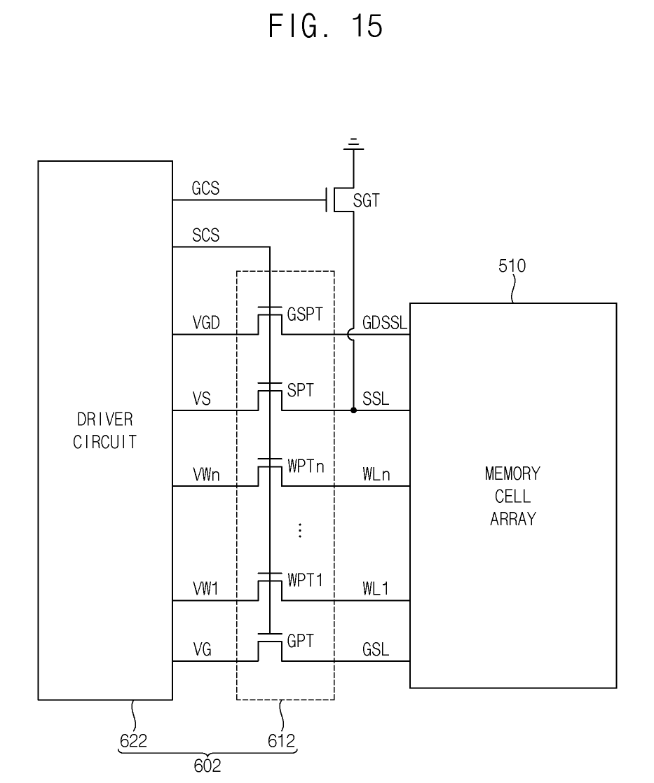

FIG. 15 is a block diagram illustrating an example of an address decoder included in a memory device of FIG. 4. The descriptions repeated with or overlapping with descriptions of FIG. 7 will be omitted in the interest of brevity.

Referring to FIG. 15, an address decoder 602 may be connected to the memory cell array 510 through a GIDL string selection line GDSSL, a string selection line SSL, wordlines WL1, ..., WLn, and a ground selection line GSL, and may include a pass switch circuit 612 and a driver circuit 622.

The pass switch circuit 612 may further include a GIDL string pass transistor GSPT connected to the GIDL string selection line GDSSL.

The driver circuit 622 may control a switching operation of the GIDL string pass transistor GSPT by a plurality of switching control signals SCS, and a timing at which a voltage VGD is applied to the memory cell array 510 may be controlled by the switching operation of the GIDL string pass transistor GSPT.

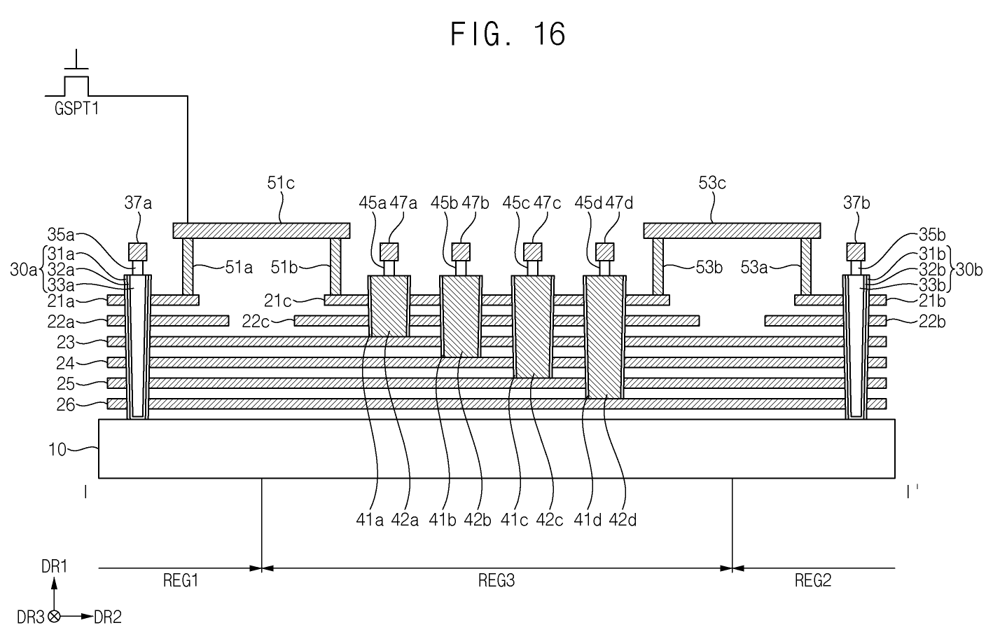

FIG. 16 is a diagram illustrating an example of a memory device including an address decoder of FIG. 15. The descriptions repeated with or overlapping with descriptions of FIG. 2A will be omitted in the interest of brevity.

Referring to FIG. 16, an example of the memory device of FIG. 2A where the sub-gate electrodes 21a and 21b are electrically connected with each other via the sub-gate electrode 21c and the first electrical connection structure and are used as a single GIDL string selection line is illustrated.

In some example implementations, the memory device may further include a first GIDL string pass transistor GSPT1. The first GIDL string pass transistor GSPT1 may be connected to the GIDL string selection line and may be disposed and connected to be adjacent to the sub-gate electrode 21a. Being adjacent to the sub-gate electrode 21a refers to being nearer to the sub-gate electrode 21a than to the sub-gate electrode 21b.

Although not illustrated in detail, the first GIDL string pass transistor GSPT1 may be disposed and connected to be adjacent to the sub-gate electrode 21b. Being adjacent to the sub-gate electrode 21b can refer to being nearer to the sub-gate electrode 21b than to the sub-gate electrode 21a.

When the sub-gate electrodes 21a and 21b are not electrically connected with each other, each of the sub-gate electrodes 21a and 21b operates as an individual GIDL string selection line, and two GIDL string pass transistors may be required to drive each GIDL string selection line.

In contrast, when the sub-gate electrodes 21a and 21b are electrically connected with each other via the sub-gate electrode 21c and the first electrical connection structure according to example implementations, the sub-gate electrodes 21a and 21b may operate as a single GIDL string selection line. Accordingly, one of the two GIDL string pass transistors described above may be omitted, so that the number of components for driving the GIDL string selection line may be reduced, and the size of the memory device may be reduced.

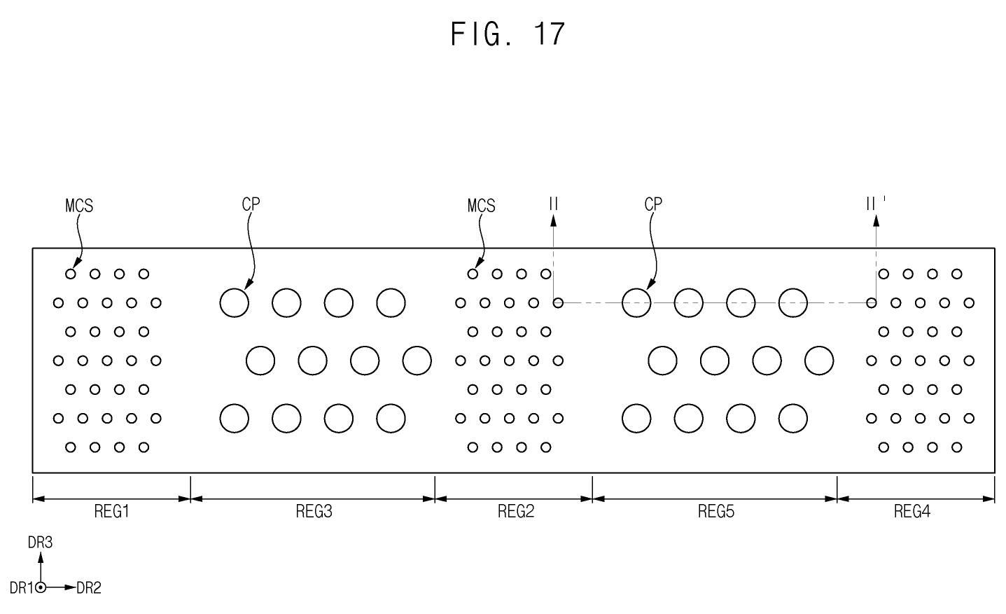

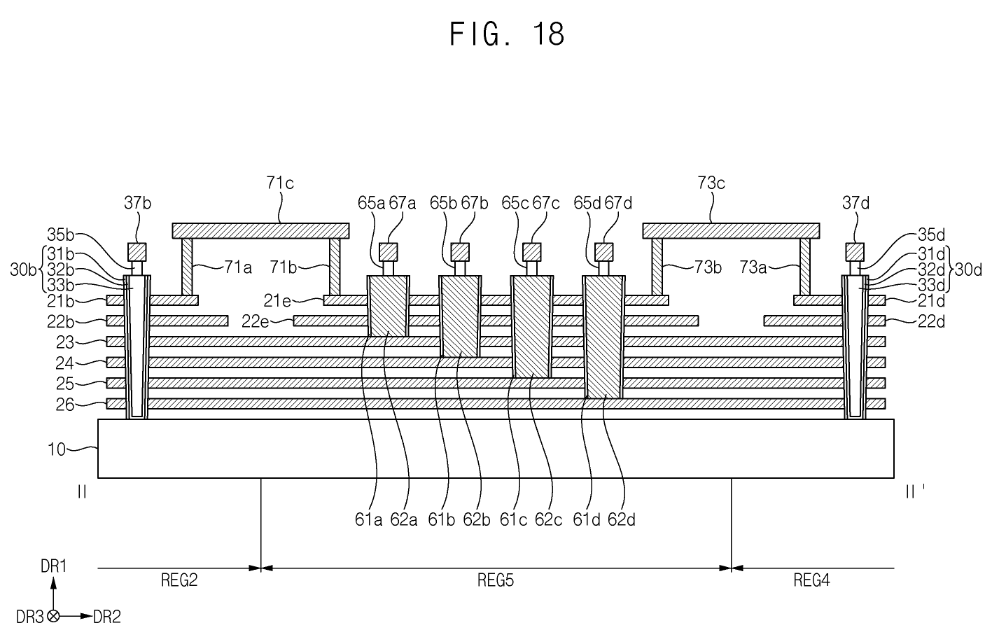

FIGS. 17 and 18 are diagrams illustrating a memory device according to example implementations. For example, FIG. 17 is a plan view of a memory device, and FIG. 18 is a cross-sectional view taken along line II-II' of FIG. 17. The descriptions repeated with or overlapping with descriptions of FIGS. 1 and 2A will be omitted in the interest of brevity.

Referring to FIGS. 17 and 18, a memory device includes a gate electrode structure, a plurality of memory channel structures MCS, a plurality of contact plugs CP, and first and second electrical connection structures, which are disposed and/or formed on a first substrate 10.

The first substrate 10 may include first, second, and third regions EG1, REG2 and, REG3, and may further include a fourth region REG4 spaced apart from the second region REG2, and a fifth region REG5 disposed between the second and fourth regions REG2 and REG4. As with the first and second regions REG1 and REG2, the fourth region REG4 may be a cell region in which the plurality of memory channel structures MCS are disposed and/or formed. As with the third region REG3, the fifth region REG5 may be a region in which the plurality of contact plugs CP are disposed and/or formed.

The gate electrode structure includes a plurality of gate electrodes 21a, 21b, 21c, 21d, 21e, 22a, 22b, 22c, 22d, 22e, 23, 24, 25 and 26. For example, the gate electrode at the uppermost level may include the sub-gate electrodes 21a, 21b, 21c, 21d and 21e that are physically separated from each other, and the gate electrode at a level under the sub-gate electrodes 21a, 21b, 21c, 21d and 21e may include the sub-gate electrodes 22a, 22b, 22c, 22d and 22e that are physically separated from each other. For example, the sub-gate electrodes 21d and 22d may be disposed on the fourth region REG4, and the sub-gate electrodes 21e and 22e may be disposed on the fifth region REG5.

The plurality of memory channel structures MCS may further include a third memory channel structure 30d. The third memory channel structure 30d may include a third filling pattern 33d, which may extend in the first direction DR1 and have a pillar shape, a third channel 32d, which may cover a sidewall and a lower surface of the third filling pattern 33d and have a cup shape, and a third charge storage structure 31d on an outer sidewall of the third channel 32d. The memory device may further include a third via 35d contacting an upper surface of the third memory channel structure 30d, and a third wiring 37d contacting an upper surface of the third via 35d.

The plurality of contact plugs CP may further include contact plugs 62a, 62b, 62c and 62d that are disposed on the fifth region REG5. The contact plugs 62a, 62b, 62c and 62d may have a structure similar to the contact plugs 42a, 42b, 42c and 42d. Spacers 61a, 61b, 61c and 61d, vias 65a, 65b, 65c and 65d, and wirings 67a, 67b, 67c and 67d may be formed with respect to the contact plugs 62a, 62b, 62c and 62d.

The second electrical connection structure may electrically connect the sub-gate electrode 21b with the sub-gate electrode 21d via the sub-gate electrode 21e, and may include vias 71a, 71b, 73a and 73b and wirings 71c and 73c. The second electrical connection structure may have a structure similar to that of the first electrical connection structure.

The sub-gate electrodes 21a, 21b and 21d at the same level may be electrically connected with each other via the first and second electrical connection structures and the floating sub-gate electrodes 21c and 22e, and can be used as a single string selection line and/or a single GIDL string selection line.

Although example implementations are illustrated that a single memory block and/or a single mat is divided into two or three cell regions and contact plugs are disposed therebetween, example implementations are not limited thereto.

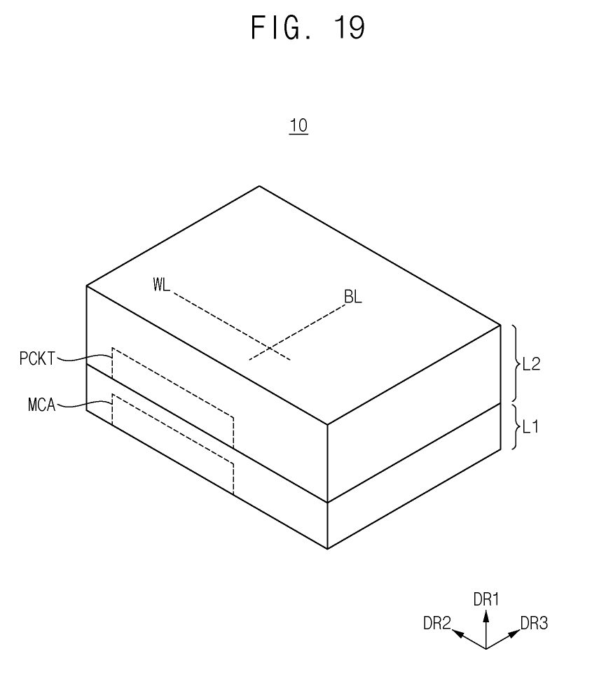

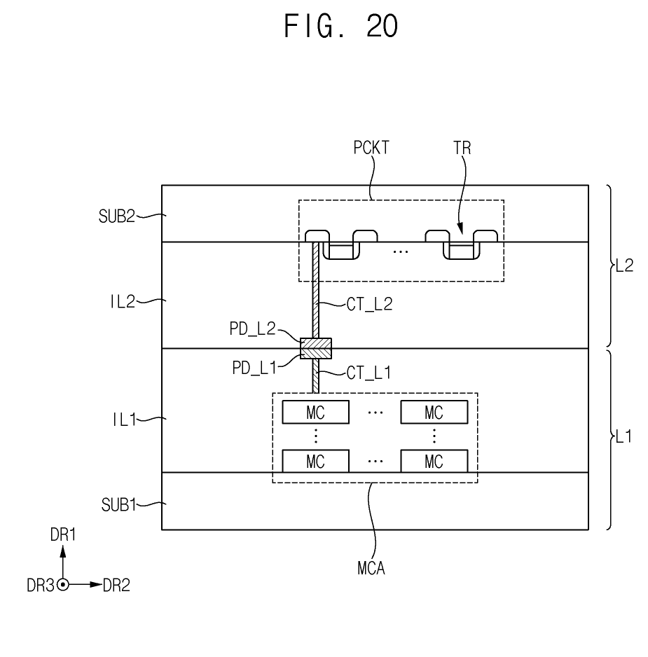

FIGS. 19 and 20 are diagrams illustrating a memory device according to example implementations.

Referring to FIGS. 19 and 20, a memory device 10 includes a first semiconductor layer L1 and a second semiconductor layer L2.

The first semiconductor layer L1 and the second semiconductor layer L2 are disposed or stacked in the first direction DR1. For example, the second semiconductor layer L2 may be stacked on the first semiconductor layer L1 in the first direction DR1, and the first semiconductor layer L1 may be disposed under (e.g., directly beneath or indirectly beneath) the second semiconductor layer L2 in the first direction DR1. However, example implementations are not limited thereto. For example, the memory device 10 may be turned over during the manufacturing process, and thus the first semiconductor layer L1 may be stacked on the second semiconductor layer L2 in the first direction DR1.

The first semiconductor layer L1 may include a first substrate SUB1, a memory cell array MCA, a plurality of wordlines WL and a plurality of bitlines BL. The first semiconductor layer L1 may further include a first pad PD_L1, a first contact CT_L1 and a first insulating layer IL1. Thus, the first semiconductor layer L1 may be referred to as a memory cell region (MCR) and/or a cell wafer.

The first substrate SUB1 may be a supporting layer that supports components (or elements) of the first semiconductor layer L1. For example, the first substrate SUB1 may be a silicon substrate, and may be referred to as a base substrate. The first insulating layer IL1 may cover the components of the first semiconductor layer L1. For example, the first insulating layer IL1 may include a plurality of insulating layers.

The memory cell array MCA, the plurality of wordlines WL and the plurality of bitlines BL may be disposed and/or formed on the first substrate SUB1. For example, each of the plurality of wordlines WL may extend in the second direction DR2, and the plurality of wordlines WL may be arranged along the first and third directions DR1 and DR3. For example, each of the plurality of bitlines BL may extend in the third direction DR3, and the plurality of bitlines BL may be arranged along the second direction DR2. For example, the memory cell array MCA may include a plurality of memory cells MC that are arranged along the first, second and third directions DR1, DR2 and DRb, and each of the plurality of memory cells MC may be electrically connected to one of the plurality of wordlines WL and one of the plurality of bitlines BL.

The first semiconductor layer (L1) may be implemented with the structure described with reference to FIGS. 1 - 18, e.g., a structure in which the contact plugs may be disposed at the center, the gate electrode structure may not have a staircase shape or a step shape, and the sub-gate electrodes that are disposed at the same level among the upper gate electrodes and spaced apart from each other may be electrically connected with each other using the at least one floating sub-gate electrode and the at least one electrical connection structure.

The second semiconductor layer L2 may include a second substrate SUB2 and a peripheral circuit PCKT. The second semiconductor layer L2 may further include a second pad PD_L2, a second contact CT_L2 and a second insulating layer IL2. Thus, the second semiconductor layer L2 may be referred to as a peripheral circuit region (PCR) and/or a peripheral wafer (or a core wafer).

As with the first substrate SUB1 and the first insulating layer IL1, the second substrate SUB2 may be a supporting layer that supports components of the second semiconductor layer L2, and the second insulating layer IL2 may cover the components of the second semiconductor layer L2.

The peripheral circuit PCKT may be disposed and/or formed on the second substrate SUB2. For example, the peripheral circuit PCKT may include a plurality of transistors TR, and various circuits may be formed by the plurality of transistors TR. For example, the peripheral circuit PCKT may include an address decoder, which is described with reference to FIGS. 7 and 15. etc.

In some example implementations, the first semiconductor layer L1 and the second semiconductor layer L2 may be manufactured separately, and then the first semiconductor layer L1 and the second semiconductor layer L2 may be connected to each other by a bonding scheme (or method). For example, the bonding scheme may represent a method of electrically or physically connecting a bonding metal pattern (e.g., the first pad PD_L1) formed in the first semiconductor layer L1 with a bonding metal pattern (e.g., the second pad PD_L2) formed in the second semiconductor layer L2. For example, the pads PD_L1 and PD_L2 may be formed of copper (Cu), and the bonding scheme may be a Cu-Cu bonding scheme. Alternatively, the pads PD_L1 and PD_L2 may be formed of aluminum (Al) or tungsten (W).

For example, the memory cell array MCA (e.g., the wordlines WL and the bitlines BL) of the first semiconductor layer L1 and the peripheral circuit PCKT of the second semiconductor layer L2 may be electrically connected to each other by the first and second pads PD_L1 and PD_L2. In other words, the memory cell MC and the transistor TR may be electrically connected to each other by the first and second contacts CT_L1 and CT_L2 and the first and second pads PD_L1 and PD_L2. For example, the memory cell MC may be electrically connected to the first contact CT_L1 and the first pad PD_L1, the transistor TR may be electrically connected to the second contact CT_L2 and the second pad PD_L2, and the memory cell MC and the transistor TR may be electrically connected to each other by electrically connecting the first pad PD_L1 with the second pad PD_L2. Although not illustrated in detail, at least one conductive line and/or contact may be further formed to connect the memory cell MC with the first pad PD_L1, and at least one conductive line and/or contact may be further formed to connect the transistor TR with the second pad PD_L2.

However, example implementations are not limited thereto, and various bonding schemes, such as a hybrid bonding scheme and a dielectric bonding scheme, may be used to electrically or physically connect the first semiconductor layer L1 with the second semiconductor layer L2.

The memory device 10 according to example implementations may have or adopt a structure in which the peripheral circuit PCKT and the memory cell array MCA are stacked. Accordingly, the memory device 10 may have a relatively small size. For example, the first semiconductor layer L1 may be manufactured by forming the memory cell array MCA on the first substrate SUB1, the second semiconductor layer L2 may be manufactured by forming the peripheral circuit PCKT on the second substrate SUB2, the second semiconductor layer L2 may be turned over, and the pads PD_L1 and PD_L2 may be connected using the bonding scheme. As a result, the first and second semiconductor layers L1 and L2 may be electrically connected in the first direction DR1.

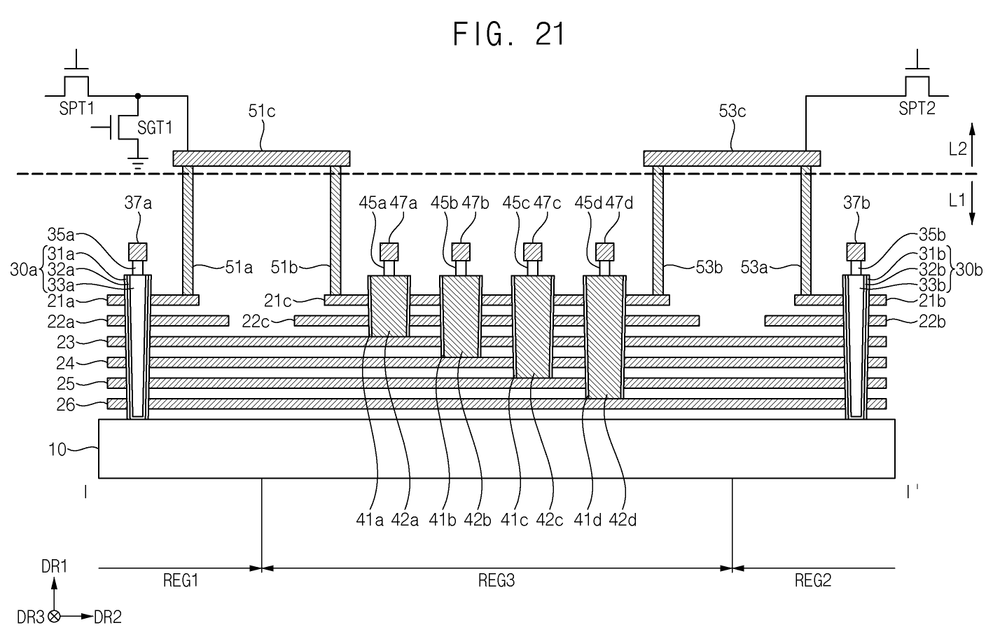

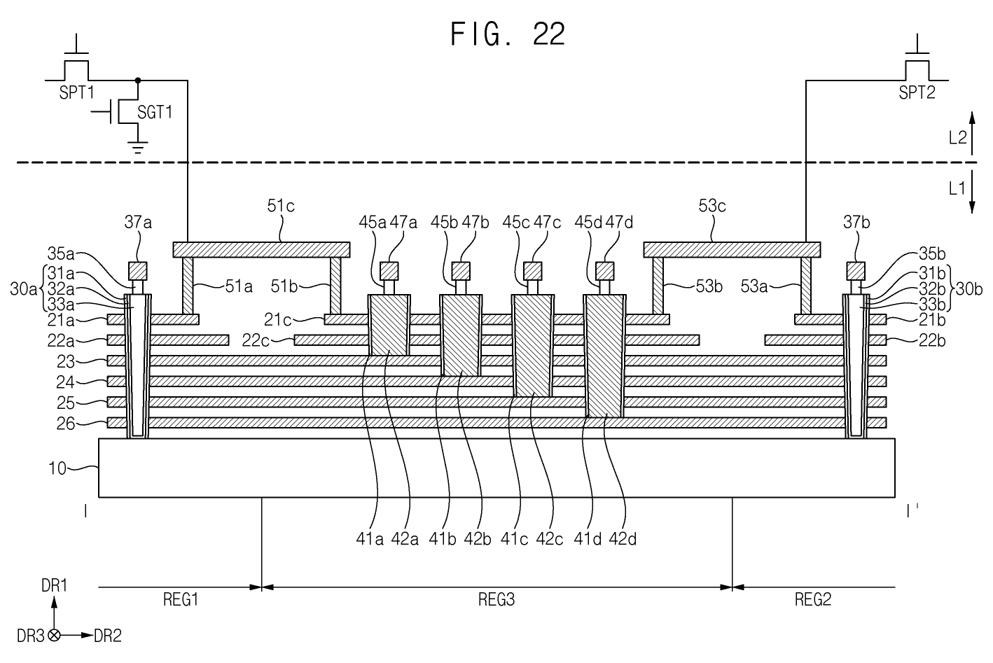

FIGS. 21 and 22 are diagrams illustrating examples of a memory device of FIGS. 19 and 20. The descriptions repeated with or overlapping with descriptions of FIGS. 2A and 8 will be omitted in the interest of brevity.

Referring to FIGS. 21 and 22, an example of the memory device of FIGS. 19 and 20 where the sub-gate electrodes 21a and 21b are electrically connected with each other via the sub-gate electrode 21c and the first electrical connection structure and are used as a single string selection line is illustrated.

In some example implementations, as illustrated in FIG. 21, a first portion of the first electrical connection structure may be included in the first semiconductor layer L1, and a second portion of the first electrical connection structure may be included in the second semiconductor layer L2. For example, among the components included in the first electrical connection structure, the wirings 51c and 53c and some portions of the vias 51a, 51b, 53a and 53b may be included in the second semiconductor layer L2.

In some example implementations, as illustrated in FIG. 22, the entire portions of the first electrical connection structure may be included in the first semiconductor layer L1.

In the examples of FIGS. 21 and 22, the gate electrode structure, the memory channel structures 30a and 30b and the contact plugs 42a, 42b, 42c and 42d may be included in the first semiconductor layer L1, and the first string pass transistor SPT1, the second string pass transistor SPT2 and the first string ground transistor SGT1 may be included in the second semiconductor layer L2.

In some example implementations, the memory device according to example implementations may be implemented by combining two or more of the examples described with reference to FIGS. 1 - 22.

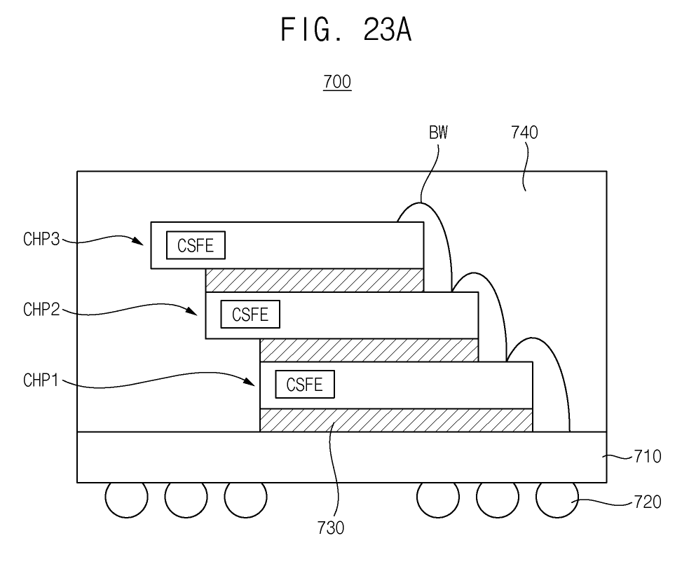

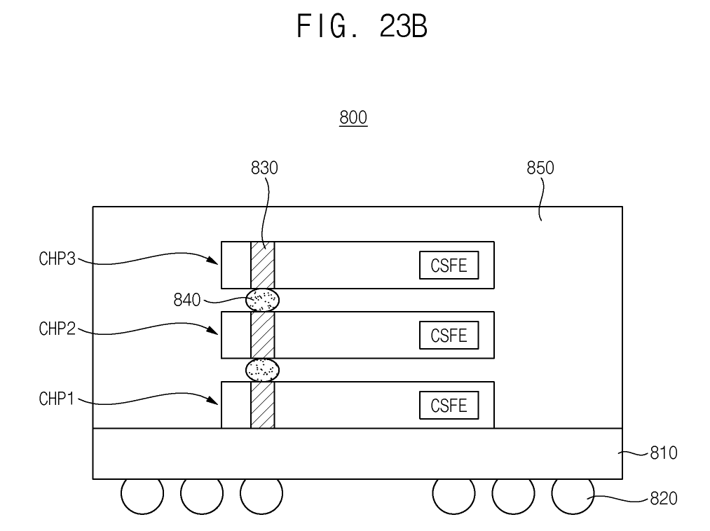

FIGS. 23A and 23B are diagrams illustrating a memory package according to example implementations.

Referring to FIG. 23A, a memory package 700 may include a base substrate 710, and a plurality of memory chips CHP1, CHP2 and CHP3 stacked on the base substrate 710.

Each of the memory chips CHP1 to CHP3 may include I/O pads IOPAD. Each of the memory chips CHP1 to CHP3 may be the memory device according to the example implementations described with reference to FIGS. 1 - 22, and may have a connection structure with a floating electrode (CSFE) according to example implementations, in which the contact plugs may be disposed at the center, the gate electrode structure may not have a staircase shape or a step shape, and the sub-gate electrodes that are disposed at the same level among the upper gate electrodes and spaced apart from each other may be electrically connected with each other using the at least one floating sub-gate electrode and the at least one electrical connection structure.

In some example implementations, the memory chips CHP1 to CHP3 may be stacked on the base substrate 710 such that a surface on which the I/O pads IOPAD are formed faces upwards. In some example implementations, with respect to each of the memory chips CHP1 to CHP3, the I/O pads IOPAD may be arranged near one side of the semiconductor substrate. As such, the memory chips CHP1 to CHP3 may be stacked scalariformly, that is, in a step shape, such that the I/O pads IOPAD of each memory chip may be exposed. In such stacked state, the memory chips CHP1 to CHP3 may be electrically connected to the base substrate 710 through a plurality of bonding wires BW.

The stacked memory chips CHP1 to CHP3 and the plurality of bonding wires BW may be fixed by a sealing member 740, and adhesive members 730 may intervene between the base substrate 710 and the memory chips CHP1 to CHP3. Conductive bumps 720 may be formed on a bottom surface of the base substrate 710 for electrical connections to an external device.

Referring to FIG. 23B, a memory package 800 may include a base substrate 810, and a plurality of memory chips CHP1, CHP2 and CHP3 stacked on the base substrate 810. The descriptions repeated with or overlapping with descriptions of FIG. 23A will be omitted in the interest of brevity.

Each of the memory chips CHP1 to CHP3 may further include a plurality of through silicon vias (TSVs) 830. Conductive bumps 820 and a sealing member 850 may be substantially the same as the conductive bumps 720 and the sealing member 740 in FIG. 23A, respectively.

In some example implementations, with respect to each of the memory chips CHP1 to CHP3, the plurality of TSVs 830 may be arranged at the same locations in each memory chip. As such, the memory chips CHP1 to CHP3 may be stacked such that the TSVs 830 of each memory chip may be completely overlapped (e.g., arrangements of the TSVs 830 may be perfectly matched in the memory chips CHP1 to CHP3). In such stacked state, the memory chips CHP1 to CHP3 may be electrically connected to one another and the base substrate 810 through the plurality of TSVs 830 and conductive material 840.

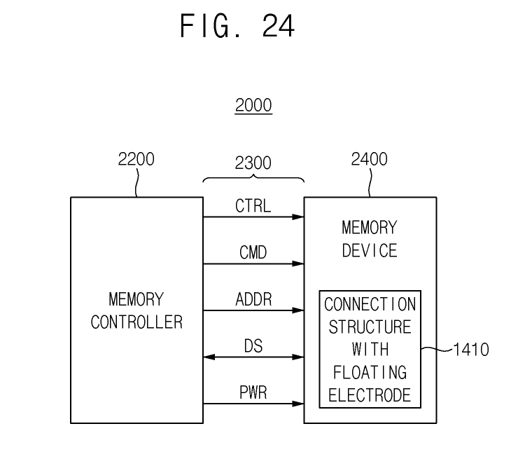

FIG. 24 is a block diagram illustrating a memory system according to example implementations.

Referring to FIG. 24, a memory system 1000 may include a memory controller 1200 and a memory device 1400. The memory system 1000 may further include a plurality of signal lines 1300 that electrically connect the memory controller 1200 with the memory device 1400.

The memory device 1400 may be controlled by the memory controller 1200. For example, based on requests from a host device (not illustrated), the memory controller 1200 may store (e.g., write or program) data into the memory device 1400, or may retrieve (e.g., read or sense) data from the memory device 1400.

The memory device 1400 may be the memory device according to the example implementations described with reference to FIGS. 1 - 22, and may have a connection structure with a floating electrode 1410 according to example implementations

The plurality of signal lines 1300 may include control lines, command lines, address lines, data I/O lines and power lines. The memory controller 1200 may transmit a command CMD, an address ADDR and a control signal CTRL to the memory device 1400 via the command lines, the address lines and the control lines, may exchange a data signal DS with the memory device 1400 via the data I/O lines, and may transmit a power supply voltage PWR to the memory device 1400 via the power lines. Although not illustrated in FIG. 24, the plurality of signal lines 1300 may further include data strobe signal (DQS) lines for transmitting a DQS signal.

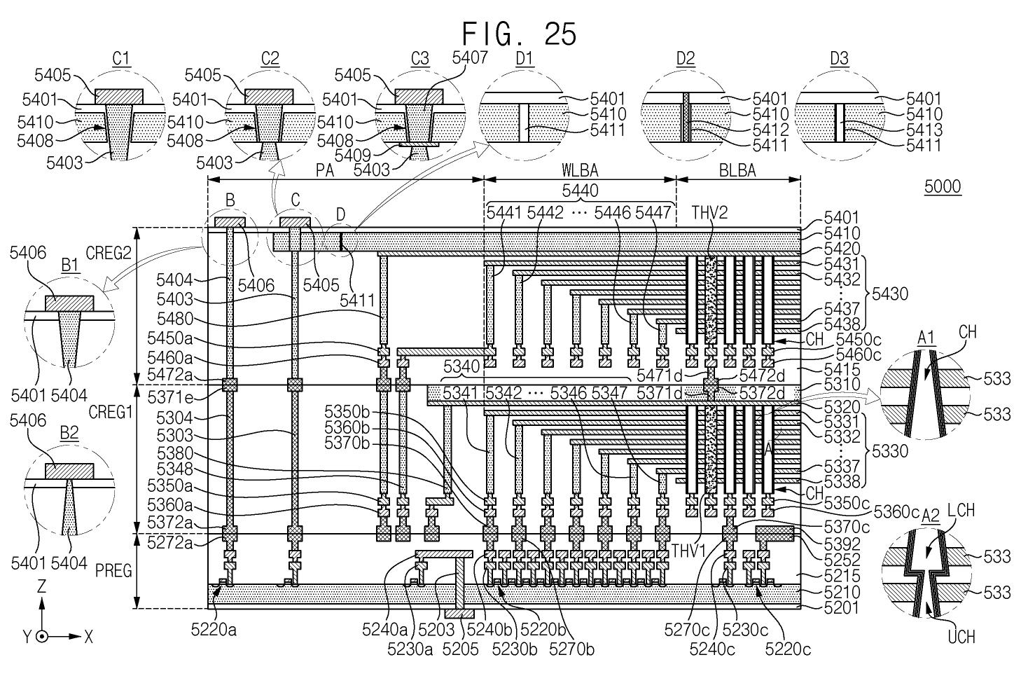

FIG. 25 is a cross-sectional view of a memory device according to example implementations.

Referring to FIG. 25, a memory device (or nonvolatile memory device) 5000 may have a chip-to-chip (C2C) structure. At least one upper chip including a cell region and a lower chip including a peripheral circuit region PREG may be manufactured separately, and then, the at least one upper chip and the lower chip may be connected to each other by a bonding method to realize the C2C structure. For example, the bonding method may refer to a method of electrically and/or physically connecting a bonding metal pattern formed in an uppermost metal layer of the upper chip to a bonding metal pattern formed in an uppermost metal layer of the lower chip. As another example, in a case in which the bonding metal patterns are formed of copper (Cu), the bonding method may be referred to as a Cu-Cu bonding method. Alternatively or additionally, the bonding metal patterns may be formed of other materials, such as, but not limited to, aluminum (Al) or tungsten (W).

The memory device 5000 may include the at least one upper chip including the cell region. For example, as illustrated in FIG. 25, the memory device 5000 may include two upper chips. However, the number of the upper chips is not limited thereto. In the case in which the memory device 5000 includes the two upper chips, a first upper chip including a first cell region CREG1, a second upper chip including a second cell region CREG2, and the lower chip including the peripheral circuit region PREG may be manufactured separately, and then, the first upper chip, the second upper chip, and the lower chip may be connected to each other by the bonding method to manufacture the memory device 5000. The first upper chip may be turned over and then may be connected to the lower chip by the bonding method, and the second upper chip may also be turned over and then may be connected to the first upper chip by the bonding method. Hereinafter, upper and lower portions of each of the first and second upper chips may be referred to based on their respective orientations before each of the first and second upper chips is turned over. For example, an upper portion of the lower chip may refer to an upper portion defined based on a +Z-axis direction, and the upper portion of each of the first and second upper chips may refer to an upper portion defined based on a -Z-axis direction in FIG. 25. However, example implementations are not limited thereto. In some example implementations, one of the first upper chip and the second upper chip may be turned over and then may be connected to a corresponding chip by the bonding method.

Each of the peripheral circuit region PREG and the first and second cell regions CREG1 and CREG2 of the memory device 5000 may include an external pad bonding region PA, a wordline bonding region WLBA, and a bitline bonding region BLBA.

The peripheral circuit region PREG may include a first substrate 5210 and a plurality of circuit elements (e.g., first circuit element 5220a, second circuit element 5220b, and third circuit element 5220c) formed on the first substrate 5210. An interlayer insulating layer 5215 including one or more insulating layers may be provided on the plurality of circuit elements 5220a to 5220c, and a plurality of metal lines electrically connected (e.g., coupled) to the plurality of circuit elements 5220a to 5220c may be provided in the interlayer insulating layer 5215. For example, the plurality of metal lines may include first metal lines (e.g., first metal line 5230a, second metal line 5230b, and third metal line 5230c) connected to the plurality of circuit elements 5220a to 5220c, and second metal lines (e.g., fourth metal line 5240a, fifth metal line 5240b, and sixth metal line 5240c) formed on the first metal lines 5230a to 5230c. The plurality of metal lines may be formed of at least one of various conductive materials. For example, the first metal lines 5230a to 5230c may be formed of tungsten (W) having a relatively high electrical resistivity, and the second metal lines 5240a to 5240c may be formed of copper (Cu) having a relatively low electrical resistivity.

The first metal lines 5230a to 5230c and the second metal lines 5240a to 5240c are illustrated and described in some example implementations. However, example implementations are not limited thereto. In some example implementations, at least one or more additional metal lines may further be formed on the second metal lines 5240a to 5240c. In such implementations, the second metal lines 5240a to 5240c may be formed of aluminum (Al), and at least some of the additional metal lines formed on the second metal lines 5240a to 5240c may be formed of copper (Cu) having an electrical resistivity lower than that of the aluminum (Al) of the second metal lines 5240a to 5240c.

The interlayer insulating layer 5215 may be disposed on the first substrate 5210 and may include an insulating material such as, but not limited to, silicon oxide (SiO) and/or silicon nitride (SiN).

Each of the first and second cell regions CREG1 and CREG2 may include at least one memory block. The first cell region CREG1 may include a second substrate 5310 and a common source line 5320. A plurality of wordlines 5330 (e.g., first wordline 5331, second wordline 5332, third wordline 5333, fourth wordline 5334, fifth wordline 5335, sixth wordline 5336, seventh wordline 5337, and eighth wordline 5338) may be stacked on the second substrate 5310 in a direction (e.g., the Z-axis direction) perpendicular to a top surface of the second substrate 5310. String selection lines and a ground selection line may be disposed on and under the plurality of wordlines 5330, and the plurality of wordlines 5330 may be disposed between the string selection lines and the ground selection line. Similarly, the second cell region CREG2 may include a third substrate 5410 and a common source line 5420, and a plurality of wordlines 5430 (e.g., first wordline 5431, second wordline 5432, third wordline 5433, fourth wordline 5434, fifth wordline 5435, sixth wordline 5436, seventh wordline 5437, and eighth wordline 5438) may be stacked on the third substrate 5410 in a direction (e.g., the Z-axis direction) perpendicular to a top surface of the third substrate 5410. Each of the second substrate 5310 and the third substrate 5410 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CREG1 and CREG2.

In some example implementations, as illustrated in a region ‘A1’, the channel structure CH may be provided in the bitline bonding region BLBA and may extend in the direction perpendicular to the top surface of the second substrate 5310 to at least partially penetrate the wordlines 5330, the string selection lines, and the ground selection line. The channel structure CH may include a data storage layer, a channel layer, and a filling insulation layer. The channel layer may be electrically connected (e.g., coupled) to a first metal line 5350c and a second metal line 5360c in the bitline bonding region BLBA. For example, the second metal line 5360c may be a bitline and may be connected to the channel structure CH through the first metal line 5350c. The bitline 5360c may extend in a first direction (e.g., a Y-axis direction) parallel to the top surface of the second substrate 5310.

In some example implementations, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 5310 to at least partially penetrate the common source line 5320 and lower wordlines 5331 and 5332. The lower channel LCH may include a data storage layer, a channel layer, and a filling insulation layer and may be connected to the upper channel UCH. The upper channel UCH may at least partially penetrate upper wordlines 5333 to 5338. The upper channel UCH may include a data storage layer, a channel layer, and a filling insulation layer, and the channel layer of the upper channel UCH may be electrically connected to the first metal line 5350c and the second metal line 5360c. As a length of a channel increases, due to characteristics of manufacturing processes, it may be difficult to form a channel having a substantially uniform width. The memory device 5000, according to some example implementations, may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a wordline located near to a boundary between the lower channel LCH and the upper channel UCH may be a dummy wordline. For example, the wordlines 5332 and 5333 adjacent to the boundary between the lower channel LCH and the upper channel UCH may be the dummy wordlines. In such an example, data may not be stored in memory cells connected to the dummy wordline. Alternatively or additionally, the number of pages corresponding to the memory cells connected to the dummy wordline may be less than the number of pages corresponding to the memory cells connected to a general wordline. A level of a voltage applied to the dummy wordline may be different from a level of a voltage applied to the general wordline, and thus, it may be possible to reduce an influence of a non-uniform channel width between the lower and upper channels LCH and UCH on an operation of the memory device.

In some example implementations, the number of the lower wordlines 5331 and 5332 at least partially penetrated by the lower channel LCH may be less than the number of the upper wordlines 5333 to 5338 at least partially penetrated by the upper channel UCH in the region ‘A2’. However, example implementations are not limited thereto. In some example implementations, the number of the lower wordlines at least partially penetrated by the lower channel LCH may be greater than or equal to the number of the upper wordlines at least partially penetrated by the upper channel UCH. Alternatively or additionally, structural features and connection relation of the channel structure CH disposed in the second cell region CREG2 may be substantially the same as those of the channel structure CH disposed in the first cell region CREG1.

In the bitline bonding region BLBA, a first through-electrode THV1 may be provided in the first cell region CREG1, and a second through-electrode THV2 may be provided in the second cell region CREG2. As illustrated in FIG. 25, the first through-electrode THV1 may at least partially penetrate the common source line 5320 and the plurality of wordlines 5330. In some example implementations, the first through-electrode THV1 may further penetrate the second substrate 5310. The first through-electrode THV1 may include a conductive material. Alternatively or additionally, the first through-electrode THV1 may include a conductive material surrounded by an insulating material. The second through-electrode THV2 may have the same and/or a substantially similar shape and structure as the first through-electrode THV1.

In some example implementations, the first through-electrode THV1 and the second through-electrode THV2 may be electrically connected (e.g., coupled) to each other through a first through-metal pattern 5372d and a second through-metal pattern 5472d. The first through-metal pattern 5372d may be formed at a bottom end of the first upper chip including the first cell region CREG1, and the second through-metal pattern 5472d may be formed at a top end of the second upper chip including the second cell region CREG2. The first through-electrode THV1 may be electrically connected (e.g., coupled) to the first metal line 5350c and the second metal line 5360c. A lower via 5371d may be formed between the first through-electrode THV1 and the first through-metal pattern 5372d, and an upper via 5471d may be formed between the second through-electrode THV2 and the second through-metal pattern 5472d. The first through-metal pattern 5372d and the second through-metal pattern 5472d may be connected (e.g., coupled) to each other by the bonding method.

In the bitline bonding region BLBA, an upper metal pattern 5252 may be formed in an uppermost metal layer of the peripheral circuit region PERI, and an upper metal pattern 5392 having the same and/or a substantially similar shape as the upper metal pattern 5252 may be formed in an uppermost metal layer of the first cell region CREG1. The upper metal pattern 5392 of the first cell region CREG1 and the upper metal pattern 5252 of the peripheral circuit region PREG may be electrically connected (e.g., coupled) to each other by the bonding method. In the bitline bonding region BLBA, the bitline 5360c may be electrically connected (e.g., coupled) to a page buffer included in the peripheral circuit region PERI. For example, some of the circuit elements 5220c of the peripheral circuit region PREG may constitute the page buffer, and the bitline 5360c may be electrically connected (e.g., coupled) to the circuit elements 5220c constituting the page buffer through an upper bonding metal pattern 5370c of the first cell region CREG1 and an upper bonding metal pattern 5270c of the peripheral circuit region PERI.

Continuing to refer to FIG. 25, in the wordline bonding region WLBA, the wordlines 5330 of the first cell region CREG1 may extend in a second direction (e.g., an X-axis direction) parallel to the top surface of the second substrate 5310 and may be connected to a plurality of cell contact plugs 5340 (e.g., first cell contact plug 5341, second cell contact plug 5342, third cell contact plug 5343, fourth cell contact plug 5344, fifth cell contact plug 5345, sixth cell contact plug 5346, and seventh cell contact plug 5347). First metal lines 5350b and second metal lines 5360b may be sequentially connected (e.g., coupled) onto the cell contact plugs 5340 connected to the plurality of wordlines 5330. In the wordline bonding region WLBA, the cell contact plugs 5340 may be connected (e.g., coupled) to the peripheral circuit region PREG through upper bonding metal patterns 5370b of the first cell region CREG1 and upper bonding metal patterns 5270b of the peripheral circuit region PERI.

The cell contact plugs 5340 may be electrically connected (e.g., coupled) to a row decoder included in the peripheral circuit region PERI. For example, some of the circuit elements 5220b of the peripheral circuit region PREG may constitute the row decoder, and the cell contact plugs 5340 may be electrically connected (e.g., coupled) to the circuit elements 5220b constituting the row decoder through the upper bonding metal patterns 5370b of the first cell region CREG1 and the upper bonding metal patterns 5270b of the peripheral circuit region PERI. In some example implementations, an operating voltage of the circuit elements 5220b constituting the row decoder may be different from an operating voltage of the circuit elements 5220c constituting the page buffer. For example, the operating voltage of the circuit elements 5220c constituting the page buffer may be greater than the operating voltage of the circuit elements 5220b constituting the row decoder.

Similarly, in the wordline bonding region WLBA, the wordlines 5430 of the second cell region CREG2 may extend in the second direction (e.g., the X-axis direction) parallel to the top surface of the third substrate 5410 and may be connected to a plurality of cell contact plugs 5440 (e.g., first cell contact plug 5441, second cell contact plug 5442, third cell contact plug 5443, fourth cell contact plug 5444, fifth cell contact plug 5445, sixth cell contact plug 5446, and seventh cell contact plug 5447). The plurality of cell contact plugs 5440 may be connected (e.g., coupled) to the peripheral circuit region PREG through an upper metal pattern of the second cell region CREG2 and lower and upper metal patterns and an eighth cell contact plug 5348 of the first cell region CREG1.

In the wordline bonding region WLBA, the upper bonding metal patterns 5370b may be formed in the first cell region CREG1, and the upper bonding metal patterns 5270b may be formed in the peripheral circuit region PERI. The upper bonding metal patterns 5370b of the first cell region CREG1 and the upper bonding metal patterns 5270b of the peripheral circuit region PREG may be electrically connected (e.g., coupled) to each other by the bonding method. The upper bonding metal patterns 5370b and the upper bonding metal patterns 5270b may be formed of aluminum (Al), copper (Cu), or tungsten (W).

In the external pad bonding region PA, a lower metal pattern 5371e may be formed in a lower portion of the first cell region CREG1, and an upper metal pattern 5472a may be formed in an upper portion of the second cell region CREG2. The lower metal pattern 5371e of the first cell region CREG1 and the upper metal pattern 5472a of the second cell region CREG2 may be connected to each other by the bonding method in the external pad bonding region PA. Similarly, an upper metal pattern 5372a may be formed in an upper portion of the first cell region CREG1, and an upper metal pattern 5272a may be formed in an upper portion of the peripheral circuit region PERI. The upper metal pattern 5372a of the first cell region CREG1 and the upper metal pattern 5272a of the peripheral circuit region PREG may be connected to each other by the bonding method.

Common source line contact plugs 5380 and 5480 may be disposed in the external pad bonding region PA. The common source line contact plugs 5380 and 5480 may be formed of a conductive material such as, but not limited to, a metal, a metal compound, and/or doped polysilicon. The common source line contact plug 5380 of the first cell region CREG1 may be electrically connected (e.g., coupled) to the common source line 5320, and the common source line contact plug 5480 of the second cell region CREG2 may be electrically connected (e.g., coupled) to the common source line 5420. A first metal line 5350a and a second metal line 5360a may be sequentially stacked on the common source line contact plug 5380 of the first cell region CREG1, and a first metal line 5450a and a second metal line 5460a may be sequentially stacked on the common source line contact plug 5480 of the second cell region CREG2.

Input/output (I/O) pads (e.g., first I/O pad 5205, second I/O pad 5405, and third I/O pad 5406) may be disposed in the external pad bonding region PA. Referring to FIG. 25, a lower insulating layer 5201 may cover a bottom surface of the first substrate 5210, and the first I/O pad 5205 may be formed on the lower insulating layer 5201. The first I/O pad 5205 may be connected to at least one of a plurality of the circuit elements 5220a disposed in the peripheral circuit region PREG through a first I/O contact plug 5203 and may be separated from the first substrate 5210 by the lower insulating layer 5201. In addition, a side insulating layer may be disposed between the first I/O contact plug 5203 and the first substrate 5210 to electrically isolate the first I/O contact plug 5203 from the first substrate 5210.

An upper insulating layer 5401 covering a top surface of the third substrate 5410 may be formed on the third substrate 5410. A second I/O pad 5405 and/or a third I/O pad 5406 may be disposed on the upper insulating layer 5401. The second I/O pad 5405 may be connected to at least one of the plurality of circuit elements 5220a disposed in the peripheral circuit region PREG through second I/O contact plugs 5403 and 5303, and the third I/O pad 5406 may be connected to at least one of the plurality of circuit elements 5220a disposed in the peripheral circuit region PREG through third I/O contact plugs 5404 and 5304.

In some example implementations, the third substrate 5410 may not be disposed in a region in which the I/O contact plug is disposed. For example, as illustrated in a region ‘B’, the third I/O contact plug 5404 may be separated from the third substrate 5410 in a direction parallel to the top surface of the third substrate 5410 and may at least partially penetrate an interlayer insulating layer 5415 of the second cell region CREG2 so as to be connected to the third I/O pad 5406. In such an example, the third I/O contact plug 5404 may be formed by at least one of various processes.

In some example implementations, as illustrated in a region ‘B1’, the third I/O contact plug 5404 may extend in a third direction (e.g., the Z-axis direction), and a diameter of the third I/O contact plug 5404 may become progressively greater toward the upper insulating layer 5401. That is, a diameter of the channel structure CH described in the region ‘A1’ may become progressively less toward the upper insulating layer 5401, but the diameter of the third I/O contact plug 5404 may become progressively greater toward the upper insulating layer 5401. For example, the third I/O contact plug 5404 may be formed after the second cell region CREG2 and the first cell region CREG1 are bonded to each other by the bonding method.

In some example implementations, as illustrated in a region ‘B2’, the third I/O contact plug 5404 may extend in the third direction (e.g., the Z-axis direction), and a diameter of the third I/O contact plug 5404 may become progressively less toward the upper insulating layer 5401. That is, similarly to the channel structure CH, the diameter of the third I/O contact plug 5404 may become progressively less toward the upper insulating layer 5401. For example, the third I/O contact plug 5404 may be formed together with the cell contact plugs 5440 before the second cell region CREG2 and the first cell region CREG1 are bonded to each other.

In some example implementations, the I/O contact plug may overlap with the third substrate 5410. For example, as illustrated in a region ‘C’, the second I/O contact plug 5403 may at least partially penetrate the interlayer insulating layer 5415 of the second cell region CREG2 in the third direction (e.g., the Z-axis direction) and may be electrically connected (e.g., coupled) to the second I/O pad 5405 through the third substrate 5410. In such an example, a connection structure of the second I/O contact plug 5403 and the second I/O pad 5405 may be realized by various methods.

In some example implementations, as illustrated in a region ‘C1’, an opening 5408 may be formed to at least partially penetrate the third substrate 5410, and the second I/O contact plug 5403 may be connected (e.g., coupled) directly to the second I/O pad 5405 through the opening 5408 formed in the third substrate 5410. In such an example, as illustrated in the region ‘C1’, a diameter of the second I/O contact plug 5403 may become progressively greater toward the second I/O pad 5405. However, example implementations are not limited thereto, and in some example implementations, the diameter of the second I/O contact plug 5403 may become progressively less toward the second I/O pad 5405.

In some example implementations, as illustrated in a region ‘C2’, the opening 5408 penetrating the third substrate 5410 may be formed, and a contact 5407 may be formed in the opening 5408. An end of the contact 5407 may be connected to the second I/O pad 5405, and another end of the contact 5407 may be connected to the second I/O contact plug 5403. Thus, the second I/O contact plug 5403 may be electrically connected (e.g., coupled) to the second I/O pad 5405 through the contact 5407 in the opening 5408. In such an example, as illustrated in the region ‘C2’, a diameter of the contact 5407 may become progressively greater toward the second I/O pad 5405, and a diameter of the second I/O contact plug 5403 may become progressively less toward the second I/O pad 5405. For example, the second I/O contact plug 5403 may be formed together with the cell contact plugs 5440 before the second cell region CREG2 and the first cell region CREG1 are bonded to each other, and the contact 5407 may be formed after the second cell region CREG2 and the first cell region CREG1 are bonded to each other.

In some example implementations illustrated in a region ‘C3’, a stopper 5409 may further be formed on a bottom end of the opening 5408 of the third substrate 5410, as compared with the implementations of the region ‘C2’. The stopper 5409 may be a metal line formed in the same layer as the common source line 5420. Alternatively or additionally, the stopper 5409 may be a metal line formed in the same layer as at least one of the wordlines 5430. The second I/O contact plug 5403 may be electrically connected (e.g., coupled) to the second I/O pad 5405 through the contact 5407 and the stopper 5409.

Similarly to the second and third I/O contact plugs 5403 and 5404 of the second cell region CREG2, a diameter of each of the second and third I/O contact plugs 5303 and 5304 of the first cell region CREG1 may become progressively less toward the lower metal pattern 5371e and/or may become progressively greater toward the lower metal pattern 5371e.

In some example implementations, a slit 5411 may be formed in the third substrate 5410. For example, the slit 5411 may be formed at a certain position of the external pad bonding region PA. As another example, as illustrated in a region ‘D’, the slit 5411 may be located between the second I/O pad 5405 and the cell contact plugs 5440 when viewed in a plan view. Alternatively or additionally, the second I/O pad 5405 may be located between the slit 5411 and the cell contact plugs 5440 when viewed in a plan view.

In some example implementations, as illustrated in a region ‘D1’, the slit 5411 may be formed to at least partially penetrate the third substrate 5410. For example, the slit 5411 may be used to prevent the third substrate 5410 from being finely cracked when the opening 5408 is formed. However, example implementations are not limited thereto, and in some example implementations, the slit 5411 may be formed to have a depth ranging from about 60 % to about 70 % of a thickness of the third substrate 5410.

In some example implementations, as illustrated in a region ‘D2’, a conductive material 5412 may be formed in the slit 5411. For example, the conductive material 5412 may be used to discharge a leakage current occurring in driving of the circuit elements in the external pad bonding region PA to the outside. In such an example, the conductive material 5412 may be connected to an external ground line.

In some example implementations, as illustrated in a region ‘D3’, an insulating material 5413 may be formed in the slit 5411. For example, the insulating material 5413 may be used to electrically isolate the second I/O pad 5405 and the second I/O contact plug 5403 disposed in the external pad bonding region PA from the wordline bonding region WLBA. Since the insulating material 5413 is formed in the slit 5411, it may be possible to prevent a voltage provided through the second I/O pad 5405 from affecting a metal layer disposed on the third substrate 5410 in the wordline bonding region WLBA.

In some example implementations, the first to third I/O pads 5205 to 5406 may be selectively formed. For example, the memory device 5000 may be realized to include only the first I/O pad 5205 disposed on the first substrate 5210, to include only the second I/O pad 5405 disposed on the third substrate 5410, or to include only the third I/O pad 5406 disposed on the upper insulating layer 5401.

In some example implementations, at least one of the second substrate 5310 of the first cell region CREG1 and the third substrate 5410 of the second cell region CREG2 may be used as a sacrificial substrate and may be completely or partially removed before and/or after a bonding process. An additional layer may be stacked after the removal of the substrate. For example, the second substrate 5310 of the first cell region CREG1 may be removed before or after the bonding process of the peripheral circuit region PREG and the first cell region CREG1, and then, an insulating layer covering a top surface of the common source line 5320 or a conductive layer for connection may be formed. Similarly, the third substrate 5410 of the second cell region CREG2 may be removed before or after the bonding process of the first cell region CREG1 and the second cell region CREG2, and then, the upper insulating layer 5401 covering a top surface of the common source line 5420 or a conductive layer for connection may be formed.

The memory device 5000 may be the nonvolatile memory device according to example implementations, and may have the connection structure using the floating electrode according to example implementations.

The example implementations may be applied to various electronic devices and systems that include the memory devices. For example, the example implementations may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

The foregoing is illustrative of example implementations and is not to be construed as limiting thereof. Although some example implementations have been described, those skilled in the art will readily appreciate that many modifications are possible in the example implementations without materially departing from the novel teachings and advantages of the example implementations. Accordingly, all such modifications are intended to be included within the scope of the example implementations as defined in the claims. Therefore, it is to be understood that the foregoing is illustrative of various example implementations and is not to be construed as limited to the specific example implementations disclosed, and that modifications to the disclosed example implementations, as well as other example implementations, are intended to be included within the scope of the appended claims.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A memory device comprising:
a gate electrode structure on a first substrate, the gate electrode structure comprising a plurality of gate electrodes stacked over an upper surface of the first substrate and spaced apart from each other, wherein each gate electrode of the plurality of gate electrodes extends parallel to the upper surface of the first substrate, wherein the plurality of gate electrodes comprises upper gate electrodes, wherein each of the upper gate electrodes comprises a plurality of sub-gate electrodes that are spaced apart from each other;
a plurality of memory channel structures extending through the gate electrode structure;
a first contact plug partially extending through the gate electrode structure and in contact with an upper surface of a first gate electrode among the plurality of gate electrodes, wherein the first contact plug extends through and is electrically insulated from a second gate electrode, among the plurality of gate electrodes, that is on the first gate electrode, wherein the upper surface of the first gate electrode faces away from the upper surface of the first substrate; and
a first electrical connection structure electrically connecting a first sub-gate electrode with a second sub-gate electrode via a third sub-gate electrode, wherein the first sub-gate electrode and the second sub-gate electrode are at a same level, wherein the first contact plug extends through the third sub-gate electrode, and wherein the third sub-gate electrode is electrically insulated from the first contact plug and from the plurality of memory channel structures.

2. The memory device of claim 1, comprising a string selection line, wherein the string selection line comprises the first sub-gate electrode and the second sub-gate electrode that is electrically connected with the first sub-gate electrode.

3. The memory device of claim 2, comprising:
a first string pass transistor connected to the string selection line, wherein the first string pass transistor is adjacent to the first sub-gate electrode;
a second string pass transistor connected to the string selection line, wherein the second string pass transistor is adjacent to the second sub-gate electrode; and
a first string ground transistor connected to the string selection line, wherein the first string ground transistor is adjacent to one of the first string pass transistor and the second string pass transistor.

4. The memory device of claim 2, comprising:
a first string pass transistor connected to the string selection line, wherein the first string pass transistor is adjacent to one of the first sub-gate electrode and the second sub-gate electrode; and
a first string ground transistor connected to the string selection line, wherein the first string ground transistor is adjacent to the first string pass transistor.

5. The memory device of claim 1, comprising a gate induced drain leakage (GIDL) sting selection line that comprises the first sub-gate electrode and the second sub-gate electrode electrically connected with the first sub-gate electrode.

6. The memory device of claim 1, wherein the third sub-gate electrode is at the same level as the first sub-gate electrode and the second sub-gate electrode.

7. The memory device of claim 1, wherein the third sub-gate electrode is at a level that is different from the level of the first sub-gate electrode and the second sub-gate electrode.

8. The memory device of claim 1, wherein the plurality of memory channel structures comprise a first memory channel structure and a second memory channel structure,
wherein the first memory channel structure is on a first region of the first substrate,
wherein the second memory channel structure is on a second region of the first substrate that is spaced apart from the first region, and
wherein the first contact plug is on a third region of the first substrate between the first region and the second region.

9. The memory device of claim 8, wherein the first sub-gate electrode is on the first region and wherein the first memory channel structure extends into the first sub-gate electrode,
wherein the second sub-gate electrode is on the second region and wherein the second memory channel structure extends into the second sub-gate electrode, and
wherein the third sub-gate electrode is on the third region.

10. The memory device of claim 8, comprising:
a second contact plug partially extending through the gate electrode structure and being in contact with an upper surface of a third gate electrode among the plurality of gate electrodes,
wherein the second contact plug is insulated from a gate electrode among the plurality of gate electrodes that is over the third gate electrode, and
wherein the upper surface of the third gate electrode faces away from the upper surface of the first substrate.

11. The memory device of claim 10, wherein the plurality of memory channel structures comprises a third memory channel structure,
wherein the third memory channel structure is on a fourth region of the first substrate that is spaced apart from the second region of the first substrate, and
wherein the second contact plug is on a fifth region of the first substrate between the second region and the fourth region.

12. The memory device of claim 1, wherein the first substrate, the gate electrode structure, the plurality of memory channel structures, and the first contact plug define a first semiconductor layer comprising a memory cell array, and
wherein the memory device comprises a second semiconductor layer on the first semiconductor layer, and
wherein the second semiconductor layer comprises a peripheral circuit on a second substrate and configured to control the memory cell array.

13. The memory device of claim 12, wherein the first semiconductor layer comprises a first portion of the first electrical connection structure, and
wherein the second semiconductor layer comprises a second portion of the first electrical connection structure.

14. The memory device of claim 12, wherein the first semiconductor layer comprises entire portions of the first electrical connection structures.

15. The memory device of claim 12, wherein the first semiconductor layer comprises a first pad, and
wherein the second semiconductor layer comprises a second pad, and
wherein the first semiconductor layer and the second semiconductor layer are electrically connected by the first pad and the second pad.

16. The memory device of claim 15, wherein the first pad and the second pad are connected to each other by a bonding scheme.

17. A memory package comprising:
a base substrate; and
a plurality of memory chips stacked on the base substrate, each memory chip of the plurality of memory chips comprising:
a gate electrode structure on a first substrate, the gate electrode structure comprising a plurality of gate electrodes stacked on an upper surface of the first substrate and spaced apart from each other, wherein each gate electrode of the plurality of gate electrodes extends parallel to the upper surface of the first substrate, wherein the plurality of gate electrodes comprises upper gate electrodes, wherein each of the upper gate electrodes comprises a plurality of sub-gate electrodes that are spaced apart from each other;
a plurality of memory channel structures extending through the gate electrode structure;
a first contact plug partially extending through the gate electrode structure and in contact with an upper surface of a first gate electrode among the plurality of gate electrodes, wherein the first contact plug extends through and is electrically insulated from a second gate electrode among the plurality of gate electrodes that is over the first gate electrode, wherein the upper surface of the first gate electrode faces away from the upper surface of the first substrate; and
a first electrical connection structure electrically connecting a first sub-gate electrode with a second sub-gate electrode via a third sub-gate electrode, wherein the first sub-gate electrode and the second sub-gate electrode are at a same level, wherein the first contact plug extends through the third sub-gate electrode, and wherein the third sub-gate electrode is electrically insulated from the first contact plug and from the plurality of memory channel structures.

18. The memory package of claim 17, comprising:
a plurality of bonding wires electrically connecting the base substrate with the plurality of memory chips.

19. The memory package of claim 17, comprising:
a plurality of through silicon vias (TSVs) electrically connecting the base substrate with the plurality of memory chips.

20. A memory device comprising:
a first substrate comprising a first region, a second region and a third region, wherein the first region and the second region are spaced apart from each other, and wherein the third region is between the first region and the second region;
a gate electrode structure on the first region, the second region and the third region of the first substrate, the gate electrode structure comprising a plurality of gate electrodes stacked and spaced apart from each other in a first direction perpendicular to an upper surface of the first substrate, wherein each gate electrode of the plurality of gate electrodes extends in a second direction that is parallel to the upper surface of the first substrate, wherein the plurality of gate electrodes comprises upper gate electrodes, wherein each of the upper gate electrodes comprises a plurality of sub-gate electrodes that are spaced apart from each other;
first memory channel structures on the first region of the first substrate, wherein the first memory channel structures extend through the gate electrode structure;
second memory channel structures on the second region of the first substrate, wherein the second memory channel structures extend through the gate electrode structure;
a first contact plug on the third region of the first substrate, wherein the first contact plug partially extends through the gate electrode structure and in contact with an upper surface of a first gate electrode among the plurality of gate electrodes, wherein the first contact plug extends through and is electrically insulated from a second gate electrode among the plurality of gate electrodes that is over the first gate electrode, wherein the upper surface of the first gate electrode faces away from the upper surface of the first substrate;
a first electrical connection structure electrically connecting a first sub-gate electrode on the first region with a second sub-gate electrode on the second region via a third sub-gate electrode on the third region, wherein the first sub-gate electrode and the second sub-gate electrode are spaced apart from each other and are at a same level, wherein the first contact plug extends through the third sub-gate electrode, wherein the third sub-gate electrode is electrically insulated from the first contact plug, the first memory channel structures, and the second memory channel structures, and wherein a single string selection line comprises the first sub-gate electrode and the second sub-gate electrode that is electrically connected with first sub-gate electrode;
a first string pass transistor connected to the string selection line, wherein the first string pass transistor is adjacent to the first sub-gate electrode
a second string pass transistor connected to the string selection line, wherein the second string pass transistor is adjacent to the second sub-gate electrode; and
a first string ground transistor connected to the string selection line, wherein the first string ground transistor is adjacent to one of the first string pass transistor and the second string pass transistor.
